(19) United States
(12) Patent Application Publication
(10) Pub. No.: US 2025/0203841 A1
(43) Pub. Date: Jun. 19, 2025

(54) DRAM CELLS AND MANUFACTURING METHODS THEREOF

(71) Applicant: Peiching LING, Taipei (TW)

(72) Inventors: Peiching LING, San Jose, CA (US); Nanray WU, Miaoli (TW); Liang-Gi YAO, Hsinchu City (TW)

(21) Appl. No.: 18/846,675

(22) PCT Filed: Nov. 8, 2023
(86) PCT No.: PCT/US2023/079024

§ 371 Date: Sep. 13, 2024

Related U.S. Application Data
(60) Provisional application No. 63/382,726, filed on Nov. 8, 2022.

(51) Int. Cl. H10B 12/00

(52) U.S. Cl. CPC H10B 12/00

(57) ABSTRACT

A semiconductor structure is provided. The semiconductor structure comprises a semiconductor layer, a first gate structure, a second gate structure, a first dielectric layer, a first capacitor and a second capacitor. The semiconductor layer comprises a first cell region and a second cell region. The first cell region comprises a first source region, a first drain region, and a first body region between the first source region and the first drain region. The second cell region comprises a second source region, a second drain region, and a second body region between the second source region and the second drain region. The first gate structure is disposed on a first side of the semiconductor layer and over the first body region, and the second gate structure is disposed on the first side of the semiconductor layer and over the second body region. The first dielectric layer is disposed on a second side of the semiconductor layer opposite from the first side. The first dielectric layer is in contact with the semiconductor layer and overlapped with both the first source region and the second source region. The first capacitor is disposed on the second side of the semiconductor layer and electrically connected to the first source region. The second capacitor is disposed on the second side of the semiconductor layer and electrically connected to the second source region. A method for manufacturing the semiconductor structure is also provided.

### RELATED APPLICATION

This application claims priority to U.S. Provisional Patent Application Ser. No. 63/382,726, filed on Nov. 8, 2022, entitled “Structures and processes including an etch stop layer,” which is incorporated herein by reference in its entirety.

### BACKGROUND

### Field of the Invention

The present disclosure relates to DRAM cells and methods for making the same; more particularly, to DRAM cells comprising a capacitor on the backside of the transistor.

### Description of Related Art

Memory devices are widely used in various applications. In memory devices, there are a lot of memory cell connected in series to form an array to store data. There are two main types of memory cells. One is non-volatile memory cell such as read-only memory (ROM) cell, erasable programmable read only memory (EPROM) cell, and electrically erasable programmable read only memory (EEPROM) cell, and the other is volatile memory cell such as dynamic random access memory (DRAM) cell and static random access memory (SRAM) cell.

Due to larger storage capacity and lower cost, DRAM is one of the most widely used memory storage device and plays a vital role in temporarily retaining data for convenient and swift access. A conventional DRAM cell may comprise a transistor and a capacitor (1T1C structure). By charging and discharging the capacitor, the DRAM cell is on either “1” or “0” state, and the transistor controls the access to the data. With the demanding of increasing the density of memory cell, the size of the memory cell have to shrink. However, the effective capacitance of each cell may be decreased accordingly because of smaller capacitor size. Therefore, the tradeoff between the capacity and device area becomes a significant challenge in the development of DRAM-based memory devices.

It is therefore desirable to have improved structures for DRAM cell and manufacturing methods thereof.

### SUMMARY

According to the present disclosure, a semiconductor structure is provided. The semiconductor structure comprises a semiconductor layer, a first gate structure, a second gate structure, a first dielectric layer, a first capacitor and a second capacitor. The semiconductor layer comprises a first cell region and a second cell region. The first cell region comprises a first source region, a first drain region, and a first body region between the first source region and the first drain region. The second cell region comprises a second source region, a second drain region, and a second body region between the second source region and the second drain region. The first gate structure is disposed on a first side of the semiconductor layer and over the first body region, and the second gate structure is disposed on the first side of the semiconductor layer and over the second body region. The first dielectric layer is disposed on a second side of the semiconductor layer opposite from the first side. The first dielectric layer is in contact with the semiconductor layer and overlapped with both the first source region and the second source region. The first capacitor is disposed on the second side of the semiconductor layer and electrically connected to the first source region. The second capacitor is disposed on the second side of the semiconductor layer and electrically connected to the second source region.

In one embodiment, a thickness of the first dielectric layer ranges from about 2 nm to about 700 nm.

In one embodiment, the semiconductor structure further comprises an isolation structure between the first source region and the second source region.

In one embodiment, the first dielectric layer overlaps and is in contact with the isolation structure.

In one embodiment, a first interface between the first dielectric layer and the first cell region extends laterally across the first source region, the first drain region, and the first body region; a second interface between the first dielectric layer and the second cell region extends laterally across the second source region, the second drain region, and the second body region; and a third interface between the first dielectric layer and the isolation structure extends from the first interface to the second interface.

In one embodiment, the first interface, the second interface, and the third interface collectively form a flat interface having a flatness less than 2 μm and a smoothness less than 2 nm.

In one embodiment, the semiconductor structure further comprises a third capacitor and a fourth capacitor on the first side of the semiconductor layer, wherein the third capacitor is electrically connected to the first source region, and the fourth capacitor is electrically connected to the second source region.

In one embodiment, the first dielectric layer comprises an etch stop layer comprising silicon nitride or silicon oxynitride.

In one embodiment, the first dielectric layer comprises an intermediate layer comprising silicon oxide or low-k dielectric material.

In one embodiment, the first capacitor comprises a first electrode electrically connected to the first source region, a second electrode, and a capacitor dielectric between the first electrode and the second electrode.

In one embodiment, each of the first electrode and the second electrode comprises polysilicon, metal, or conductive metal compound.

In one embodiment, the capacitor dielectric comprises high-k material.

In one embodiment, the first electrode is container-shaped, pillar-shaped, multi-fin-shaped, or plate-shaped.

In one embodiment, the semiconductor structure further comprises a first contact structure extending through the first dielectric layer and a second contact structure extending through the first dielectric layer, wherein the first capacitor is electrically connected to the first source region through the first contact structure, and the second capacitor is electrically connected to the second source region through the second contact structure.

In one embodiment, a height of the first contact structure is substantially equal to a thickness of the first dielectric layer.

In one embodiment, a height of the first contact structure is in a range between about 2 nm and about 700 nm.

In one embodiment, a lateral interval between the first contact structure and the second contact structure is less than 2.5 times a minimum critical dimension.

In one embodiment, the semiconductor layer comprises a single crystalline semiconductor material.

According to the present disclosure, a method for manufacturing a semiconductor structure is provided. The method comprises providing a semiconductor substrate comprising a first substrate, a second substrate on the first substrate, and a bonding layer between the first substrate and the second substrate (step (a)). The method comprises forming a source region and a drain region in the second substrate and forming a gate structure on a first side of the second substrate (step (b)). The method comprises adding a third substrate on the first side of the second substrate, wherein the second substrate is between the third substrate and the first substrate (step (c)). The method comprises removing the first substrate and the bonding layer (step (d)). The method comprises forming a first capacitor on a second side of the second substrate opposite from the first side, wherein the first capacitor is electrically connected to the source region (step (e)).

In one embodiment, the semiconductor substrate further comprises an etch stop layer between the bonding layer and the second substrate, and the method further comprises (f) removing at least a portion of the etch stop layer before the step (e).

In one embodiment, the bonding layer comprises silicon oxide, and the etch stop layer comprises silicon nitride, silicon oxynitride, doped semiconductor material, undoped semiconductor material, metal, or conductive metal compound.

In one embodiment, the step (f) comprises forming an opening extending through the etch stop layer to expose the source region and forming a contact structure in the opening, and the step (e) comprises forming the first capacitor electrically connected to the contact structure.

In one embodiment, the second substrate comprises silicon, germanium, silicon germanium, gallium arsenide (GaAs), indium phosphide (InP), silicon carbide (SiC), or gallium nitride (GaN).

In one embodiment, the method further comprises forming a dielectric layer on the second side of the second substrate after the step (d).

In one embodiment, the method further comprises forming an opening extending through the dielectric layer to expose the source region and forming a contact structure in the opening, wherein the step (e) comprises forming the first capacitor electrically connected to the contact structure.

In one embodiment, the semiconductor substrate further comprises an intermediate layer between the etch stop layer and the second substrate.

In one embodiment, the intermediate layer comprises silicon oxide or low-k dielectric material.

In one embodiment, the step (f) comprises removing the etch stop layer to expose the intermediate layer.

In one embodiment, the method further comprises forming an opening extending through the intermediate layer to expose the source region and forming a contact structure in the opening, wherein the step (e) comprises forming the first capacitor electrically connected to the contact structure.

In one embodiment, the method further comprises forming interconnect structures on the first side of the second substrate before the step (c), wherein the interconnect structures are electrically connected to the drain region or the gate structure.

In one embodiment, the method further comprises forming a second capacitor on the first side of the second substrate before the step (c), wherein the second capacitor is electrically connected to the source region.

In one embodiment, the step (d) comprises etching the bonding layer with a first etchant. In one embodiment, the step (d) comprises completely removing the bonding layer of the semiconductor substrate.

In one embodiment, the step (f) comprises etching the etch stop layer with a second etchant. In one embodiment, the method further comprises (g) forming an isolation structure before the step (c).

In one embodiment, the step (g) comprises removing a portion of the second substrate to form a trench extending through the second substrate (step(g1)). The step (g) comprises forming an etch stop layer on a bottom surface of the trench (step(g2)). The step (g) comprises forming the isolation structure in the trench (step(g3)).

In one embodiment, the step (d) comprises removing the first substrate to expose the bonding layer (step(d1)). The step (d) comprises removing the bonding layer to expose the etch stop layer (step(d2)).

In the present disclosure, a new DRAM cell comprising one transistor and two capacitors structure (1T2C) is introduced. The manufacturing methods thereof is also introduced.

### BRIEF DESCRIPTION OF THE DRAWINGS

FIG. 1 is a schematic view to illustrate a semiconductor structure according to the present disclosure.

FIGS. 2A to 2K are schematic views to illustrate intermediate stages in the manufacture of a semiconductor structure similar to the semiconductor structure as shown in FIG. 1 according to the present disclosure.

FIG. 3A to 3D are schematic views to illustrate intermediate stages in the manufacture of a semiconductor structure similar to the semiconductor structure as shown in FIG. 1 according to the present disclosure.

FIG. 4 is a schematic view to illustrate a semiconductor structure according to the present disclosure.

FIG. 5 is a schematic view to illustrate a semiconductor structure according to the present disclosure.

FIG. 6 is a schematic view to illustrate a semiconductor structure according to the present disclosure.

FIG. 7 is a schematic view to illustrate a semiconductor structure according to the present disclosure.

FIG. 8A to 8J are schematic views to illustrate intermediate stages in the manufacture of a semiconductor structure similar to the semiconductor structure as shown in FIG. 1 according to the present disclosure.

FIG. 9A to 9H are schematic views to illustrate intermediate stages in the manufacture of a semiconductor structure according to the present disclosure.

### DETAILED DESCRIPTION OF PREFERRED EMBODIMENTS

The terminology used in the description presented below is intended to be interpreted in its broadest reasonable manner, even though it is used in conjunction with a detailed description of certain specific embodiments of the technology. Certain terms may even be emphasized below; however, any terminology intended to be interpreted in any restricted manner will be specifically defined as such in this Detailed Description section. Components and achievement of a semiconductor structure or device, according to the present disclosure may be illustrated in the following drawings and embodiments. However, the size and shape shown on drawings for the semiconductor structure or device do not limit the features of the present disclosure.

The phrase “on” used in this application can mean directly on or indirectly on with intervening elements or layers. The spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

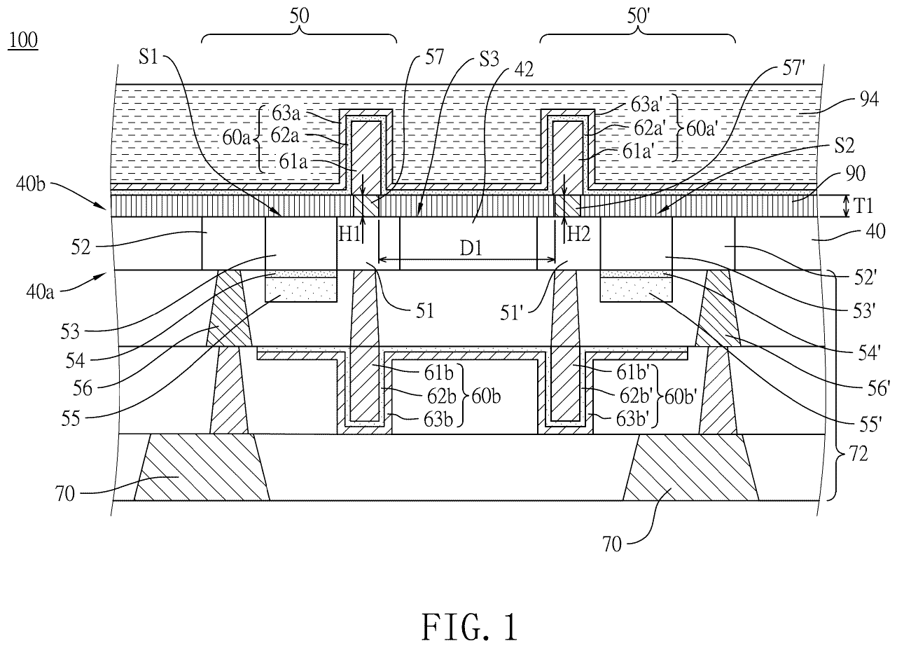

FIG. 1 is a schematic view to illustrate an embodiment of a semiconductor structure according to the present disclosure. As shown in FIG. 1, a semiconductor structure 100 comprises a semiconductor layer 40, a first gate structure 55 and a second gate structure 55′ on a first side 40a of the semiconductor layer 40, a first dielectric layer 90 on a second side 40b of the semiconductor layer 40 opposite from the first side 40a, and a first capacitor 60a and a second capacitor 60a′ on the second side 40b of the semiconductor layer 40.

The semiconductor layer 40 comprises a layer of a semiconductor material. The semiconductor material of the semiconductor layer 40 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The semiconductor layer 40 may be a single crystalline semiconductor substrate, for example, made of silicon, germanium, silicon germanium, gallium arsenide (GaAs), indium phosphide (InP), silicon carbide (SiC), or gallium nitride (GaN). In one embodiment, the thickness of the semiconductor layer 40 may be in a range between 5 nm and 0.2 μm. For example, the thickness of the semiconductor layer 40 may be 10 nm, 25 nm, 50 nm, or 100 nm. These values are merely examples and are not intended to be limiting. The semiconductor layer 40 comprises a first cell region 50 and a second cell region 50′. The first cell region 50 comprises a first source region 51, a first drain region 52, and a first body region 53. Each of the first source region 51, the first drain region 52, and the first body region 53 comprises semiconductor material(s). The first body region 53 is a region between the first source region 51 and the first drain region 52.

In one embodiment, the first source region 51 and the first drain region 52 may be doped with a first type of dopants (e.g. p-type dopants such as boron, aluminum, gallium, indium, the like, or combinations thereof; or n-type dopants such as phosphorus, arsenic, antimony, bismuth, the like, or combinations thereof), and the first body region 53 may be doped with a second type of dopants, which is different from the first type of dopants. In one embodiment, the doping concentration of the first source region 51 and the first drain region 52 may be from about 3.0×10¹⁹ atoms/cm³ to about 3.0×10²¹ atoms/cm³. In one embodiment, the doping concentration of the first channel region 53 may be from about 1.0×10¹⁵ atoms/cm³ to about 1.0×10¹⁹ atoms/cm³. These values are merely examples and are not intended to be limiting. In one embodiment, the first source region 51, the second source region 51′, the first drain region 52, and the second drain region 52′ may be doped with the first type of dopants, and the first body region 53 may be undoped. In the embodiment shown in FIG. 1, the first source region 51 and the first drain region 52 extend through the thickness of the first semiconductor layer 40.

The second cell region 50′ comprises a second source region 51′, a second drain region 52′, and a second body region 53′. The second source region 51′, the second drain region 52′, and the second body region 53′ may be similar to the first source region 51, the first drain region 52, and the first body region 53, respectively. Each of the second source region 51′, the second drain region 52′, and the second body region 53′ comprises semiconductor material(s). The second body region 53′ is a region between the second source region 51′ and the second drain region 52′. In some embodiments, the second source region 51′ and the second drain region 52′ may be doped with the same type of dopant as the first source region 51 and the second drain region 52′, and the second body region 53′ may be doped with the same type of dopant as the first body region 53. In the embodiment shown in FIG. 1, the second source region 51′ and the second drain region 52′ extend through the thickness of the first semiconductor layer 40.

The first gate structure 55 is disposed on the first side 40a of the semiconductor layer 40 and over the first body region 53. A first gate dielectric 54 may be disposed between the first body region 53 and the first gate structure 55. The first source region 51, the first drain region 52, the first body region 53, the first gate dielectric 54 and the first gate structure 55 may function as a first transistor. Similarly, the second gate structure 55′ is disposed on the first side 40a of the semiconductor layer 40 and over the second body region 53′. A second gate dielectric 54′ may be disposed between the second body region 53′ and the second gate structure 55′, and the second source region 51′, the second drain region 52′, the second body region 53′, the second gate dielectric 54′, and the second gate structure 55′ may function as a second transistor.

The first gate dielectric 54 and the second gate dielectric 54′ may each comprise dielectric material such as silicon oxide, silicon nitride, silicon oxynitride, high dielectric constant (high-k) dielectric material, including but not limited to hafnium silicate, zirconium silicate, hafnium dioxide, and zirconium dioxide, any suitable materials, or combinations thereof. The first gate structure 55 and the second gate structure 55′ may each comprise conductive material. The conductive material, by way of example and not limitation, can include doped polycrystalline or amorphous silicon, germanium, silicon germanium, a metal (e.g., tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further include dopants that are incorporated during or after deposition. In some embodiments, the first gate structure 55 and the second gate structure 55′ may each comprise a stack of conductive material layers.

The semiconductor structure 100 comprises a first capacitor 60a and a second capacitor 60a′ on the second side 40b of the semiconductor layer 40. The first capacitor 60a is electrically connected to the first source region 51, and the second capacitor 60a′ is electrically connected to the second source region 51′. As such, the first capacitor 60a and the second capacitor 60a′ may each function as a capacitor for a memory cell. The first capacitor 60a may comprise a first electrode 61a, a second electrode 63a, and a capacitor dielectric 62a between the first electrode 61a and the second electrode 63a, wherein the first electrode 61a of the first capacitor 60a is electrically connected to the first source region 51. The second capacitor 60a′ may be substantially similar to the first capacitor 60a. The second capacitor 60a′ may comprise a first electrode 61a′, a second electrode 63a′, and a capacitor dielectric 62a′ between the first electrode 61a′ and the second electrode 63a′, wherein the first electrode 61a′ of the second capacitor 60a′ is electrically connected to the second source region 51′. The first electrode 61a and 61a′ and the second electrode 63a and 63a′ may each comprise at least one conductive material, including but not limited to metal, e.g., W, Ni, Ta, Pt, Cu, Ag, Au, Al, Mo, Ti, Ir, or Ru; doped semiconductor material, e.g., doped-polysilicon, doped-germanium; conductive metal compound such as metal silicide, metal carbide, or metal nitride, e.g., WN, TaN, TaSi, TiN, TiSi, TiSiN, TiAlN, MON, IrOx, RuOx, or RuTiN. The capacitor dielectric 62a and 62a′ may each comprise silicon oxide, or high-k dielectric material, including but not limited to hafnium silicate, zirconium silicate, hafnium dioxide, and zirconium dioxide, any suitable materials, and/or combinations thereof.

In the embodiment shown in FIG. 1, both the first electrode 61a of the first capacitor 60a and the first electrode 61a′ of the second capacitor 60a′ are pillar-shaped. However, the shape of the first electrodes 61a and 61a′ may be adjusted according to actual application. In the embodiment shown in FIG. 1, the second electrode 63a of the first capacitor 60a and the second electrode 63a′ of the second capacitor 60a′ are electrically connected to each other. The second electrodes 63a and 63a′ may be further connected to second electrodes of other capacitors connected to other cell regions (not shown) depending on the design of memory array. By including capacitors on the second side of the semiconductor layer, more capacitors can be connected to a cell region (e.g., capacitors on each side of the semiconductor can be connected to a source region of a memory cell), which may increase the equivalent capacitance of each cell and may provide required capacitance for a memory cell (e.g., a DRAM cell) having a smaller cell size. Also, the capacitors on the second side of the semiconductor layer in present disclosure may have more flexibility in the shape and size of the capacitors, which may increase the equivalent capacitance and/or improve performance of each cell.

The first dielectric layer 90 is disposed on the second side 40b of the semiconductor layer 40 and in contact with the semiconductor layer 40. The first dielectric layer 90 may extend across a plurality of device region in the semiconductor layer 40. As shown in FIG. 1, the first dielectric layer 90 is overlapped with the first source region 51, the first drain region 52, and the first body region 53 of the first cell region 50 as well as the second source region 51′, the second drain region 52′, and the second body region 53′ of the second cell region 50′. Despite that contacts (e.g., the first contact structure 57 and the second contact structure 57′) may extend through the first dielectric layer 90 for desired electrical connection, the first dielectric layer 90 extends continuously from a position above the first cell region 50 to a position above the second cell region 50′. As such, the first dielectric layer 90 provides electrical isolation between regions in the semiconductor layer 40 (e.g., the first drain region 52, the first body region 53, the second drain region 52′, and the second body region 53′) and element(s) and/or portion(s) of element disposed on the second side 40b of the semiconductor layer 40 (e.g., the first electrode 61a and 61a′ and the second electrode 63a and 63a′). The first dielectric layer 90 may also provide electrical isolation between the first contact structure 57 and the second contact structure 57′. In one embodiment, the first dielectric layer 90 may comprise one or more layers of dielectric material such as silicon oxide, silicon oxynitride, low-k dielectric material, a combination thereof, and/or other applicable material. In some embodiments, a thickness T1 of the first dielectric layer 90 ranges from about 2 nm to about 700 nm. In some embodiments, a thickness T1 of the first dielectric layer 90 ranges from about 2 nm to about 30 nm.

The semiconductor structure 100 may further comprise an isolation structure 42, such as a shallow trench isolation (STI) structure, located between the first source region 51 and the second source region 51′. The isolation structure 42 may comprise silicon oxide, silicon nitride, silicon oxynitride, low-k dielectric material, a combination thereof, and/or other suitable material. In one embodiment, the first dielectric layer 90 is in contact with and overlaps the isolation structure 42.

As shown in FIG. 1, A first interface S1 between the first dielectric layer 90 and the first cell region 50 of the semiconductor layer 40 extends laterally across the first source region 51, the first drain region 52, and the first body region 53 of the first cell region 50; and a second interface S2 between the first dielectric layer 90 and the second cell region 50′ of the semiconductor layer 40 extends laterally across the second source region 51′, the second drain region 52′, and the second body region 53′ of the second source region 51′. A third interface S3 between the first dielectric layer 90 and the isolation structure 42 extends from the first interface S1 to the second interface S2. Each of the first interface S1, the second interface S2, and the third interface S3 is flat, such that the first interface S1, the second interface S2, and the third interface S3 collectively form a flat interface S. In some embodiments, the flat interface S has a flatness less than 2 μm across numerous cell regions within the same wafer on which the cells are manufactured. In some embodiments, the flat interface S has a smoothness with a peak-to-valley height less than 2 nm over a span of the first interface S1, the second interface S2, and the third interface S3. However, the disclosure is not limited thereto. With a flat interface between the first dielectric layer and the cell regions, the plurality of transistors in a memory array may have more stable and more uniform electrical performance and less leakage current due to less variations across cell regions and/or less defects occurred at the interface, especially when the semiconductor layer in which the cell regions is located is thin.

In the embodiment shown in FIG. 1, the semiconductor structure further comprises a first contact structure 57 and a second contact structure 57′. The first contact structure 57 may extend through the first dielectric layer 90, and the first electrode 61a of the first capacitor 60a may be electrically connected to the first source region 51 through the first contact structure 57. Similarly, the second contact structure 57′ may extend through the first dielectric layer 90, and the first electrode 61a′ of the second capacitor 60a′ may be electrically connected to the second source region 51′ through the second contact structure 57′. The first contact structure 57 and the second contact structure 57′ may each comprise polysilicon, metal, conductive metal compound, combinations thereof, or multi-layers thereof. In one embodiment, the first contact structure 57 and the first electrode 61a of the first capacitor 60a may be formed by the same material, and the second contact structure 57′ and the first electrode 61a′ of the second capacitor 60a′ may be formed by the same material. In one embodiment, the first contact structure 57 and the first electrode 61a of the first capacitor 60a may be formed integrally, and the second contact structure 57′ and the first electrode 61a′ of the second capacitor 60a′ may be formed integrally.

The first contact structure 57 and the second contact structure 57′ may be formed in openings in the first dielectric layer 90. As shown in FIG. 1, a height H1 of the first contact structure 57 is substantially equal to the thickness T1 of the first dielectric layer 90. In one embodiment, the height H1 of the first contact structure is in a range between about 2 nm and about 700 nm. A height H2 of the second contact structure 57′ may be substantially equal to the height H1 of the first contact structure 57. In one embodiment, the first dielectric layer 90 extends continuously between the first contact structure 57 and the second contact structure 57′ and provides electrical isolation between the first contact structure 57 and the second contact structure 57′. As such, the lateral interval D1 between the first contact structure 57 and the second contact structure 57′ may be reduced. The cell size of a unit cell may be reduced accordingly. In some embodiments, a lateral interval D1 between the first contact structure 57 and the second contact structure 57′ may be less than 2.5 times a minimum critical dimension (F).

In the embodiment shown in FIG. 1, dielectric layers 72 may be disposed on the first side 40a of the semiconductor layer 40. The dielectric layer 72 may include interlayer dielectric (ILD) layers and/or inter-metal dielectric (IMD) and may comprise dielectric material such as silicon oxide, silicon oxynitride, low dielectric constant (low-k) dielectric materials, a combination thereof, and/or other suitable material. Exemplary low-k dielectric materials include hydrogen silsesquioxane (HSQ), fluoride silicate glass (FSG), phosphosilicate glass (PSG), borophosphosilicate glass (BPSG), silicon carbon material, Spin-On-Glass, other suitable low-k dielectric materials, and/or a combination thereof.

In one embodiment shown in FIG. 1, the semiconductor structure 100 may further comprise a third capacitor 60b and a fourth capacitor 60b′ on the first side 40a of the semiconductor layer 40. The third capacitor 60b is electrically connected to the first source region 51, and the fourth capacitor 60b′ is electrically connected to the second source region 51′. As such, the third capacitor 60b and the first capacitor 60a may function as capacitors for a memory cell, and the fourth capacitor 60b′ and the second capacitor 60a′ may function as capacitors for another memory cell. However, in some embodiments, the third capacitor 60b and the fourth capacitor 60b′ are not necessarily required. The third capacitor 60b comprises a first electrode 61b, a second electrode 63b, and a capacitor dielectric 62b disposed between the first electrode 61b and the second electrode 63b. The fourth capacitor 60b′ comprises a first electrode 61b′, a second electrode 63b′, and a capacitor dielectric 62b′ disposed between the first electrode 61b′ and the second electrode 63b′. In one embodiment, the first electrode 61b and 61b′ and the second electrode 63b and 63b′ may each comprise at least one conductive material, including but not limited to metal, conductive metal compound, or doped semiconductor material, e.g., doped-polysilicon, doped-germanium. The capacitor dielectric 62b and 62b′ may each comprise silicon oxide, high-k dielectric material, including but not limited to hafnium silicate, zirconium silicate, hafnium dioxide, zirconium dioxide, any suitable materials, and/or combinations thereof. The second electrodes 63b and 63b′ may be electrically connected to each other and may be further connected to second electrodes of other capacitors connected to other cell regions (not shown) depending on the design of memory array.

In one embodiment, the semiconductor structure 100 may further comprise a first drain contact structure 56 and a second drain contact structure 56′. The first drain contact structure 56 is physically and electrically coupled to the first drain region 52, and the second drain contact structure 56′ is physically and electrically coupled to the second drain region 52′. In one embodiment, the first drain contact structure 56 and the second drain contact structure 56′ may be formed through one or more of the dielectric layers 72. The first drain contact structure 56 and the second drain contact structure 56′ may each individually comprise titanium nitride, tantalum nitride, tungsten, ruthenium, aluminum, copper, some other suitable material(s), or a combination of the foregoing.

The semiconductor structure 100 may further comprise interconnect structures 70. The interconnect structures 70 may include conductive features (e.g., conductive lines and vias) electrically connected to the first drain region 52 and/or the second drain region 52′ and/or conductive features electrically connected to the first gate structure 55 and/or the second gate structure 55′. The interconnect structures 70 may comprise titanium nitride, tantalum nitride, tungsten, ruthenium, aluminum, copper, some other suitable material(s), or a combination of the foregoing.

In one embodiment, the semiconductor structure may further comprise a second dielectric layer 94 on the second side 40b of the semiconductor layer 40. The first dielectric layer 90 is disposed between the second dielectric layer 94 and the semiconductor layer 40. The second dielectric layer 94 may comprise one or more layers of dielectric material such as silicon oxide, silicon oxynitride, low-k dielectric material, a combination thereof, and/or other applicable material. In one embodiment, the second dielectric layer 94 may comprise the same material as the first dielectric layer 90. In the embodiment shown in FIG. 1, the second dielectric layer 94 surrounds the first capacitor 60a and the second capacitor 60a′. However, it is possible that only a portion of the first capacitor 60a or a portion of the second capacitor 60a′ is surrounded by the second dielectric layer 94 depending on actual needs and the design of memory array.

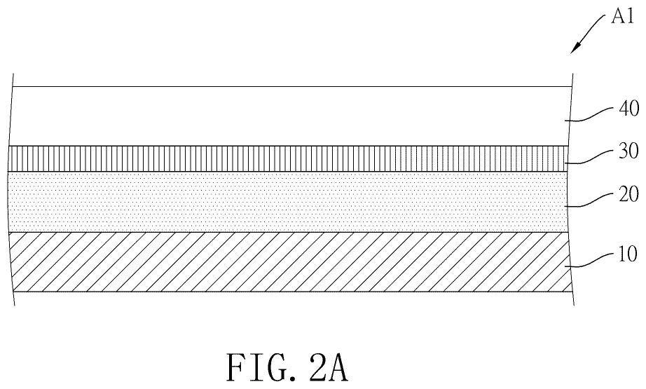

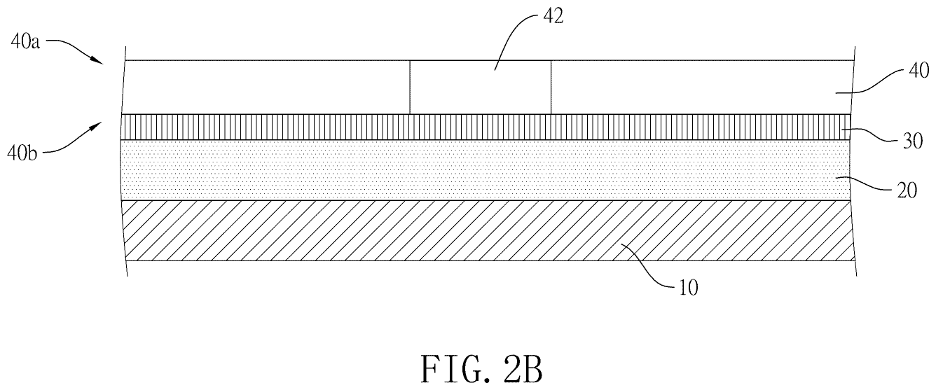

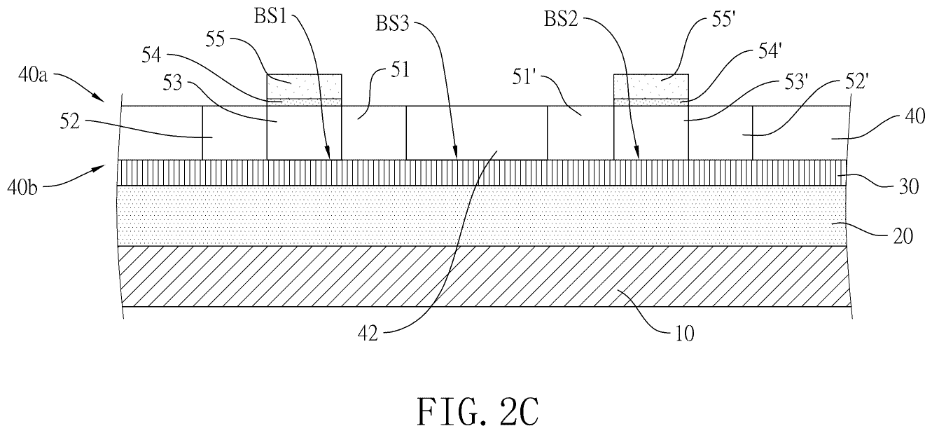

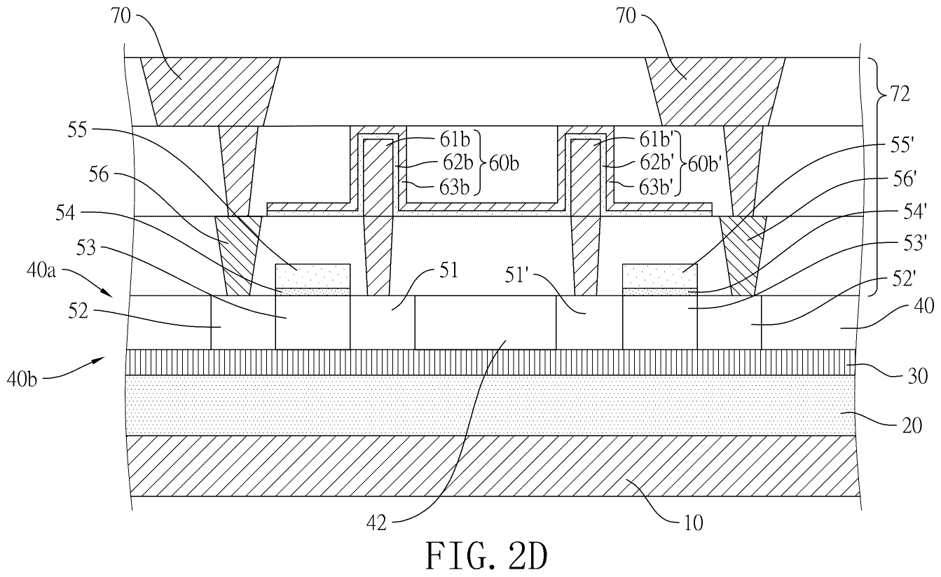

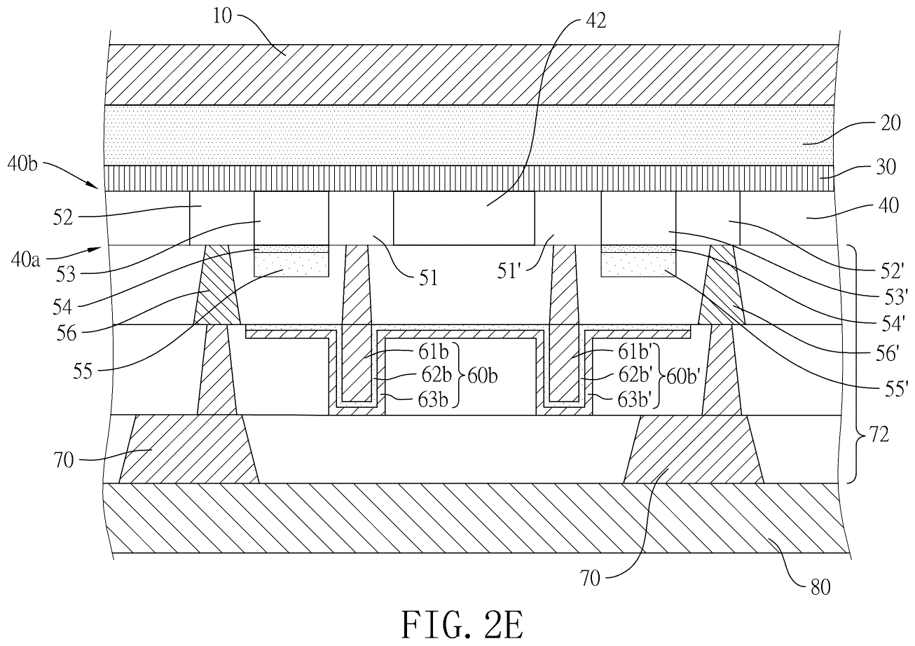

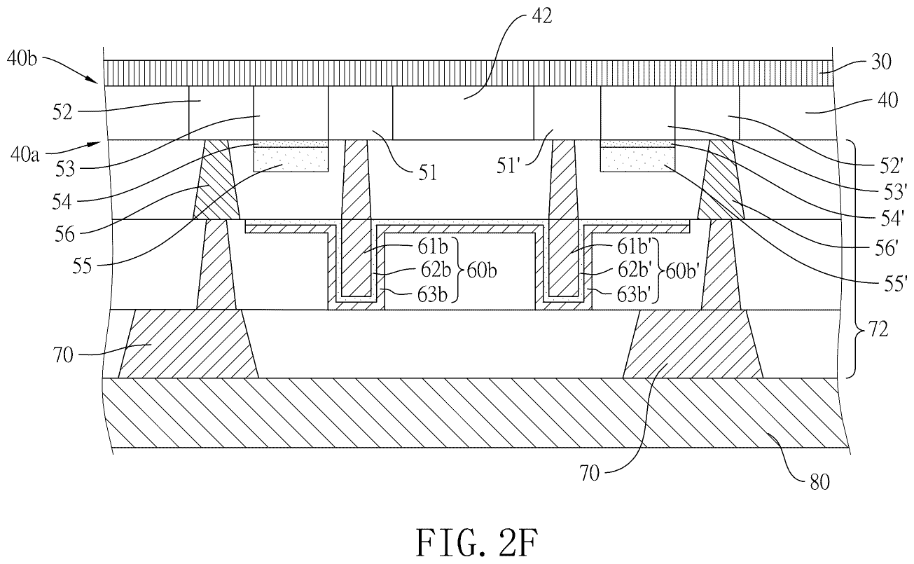

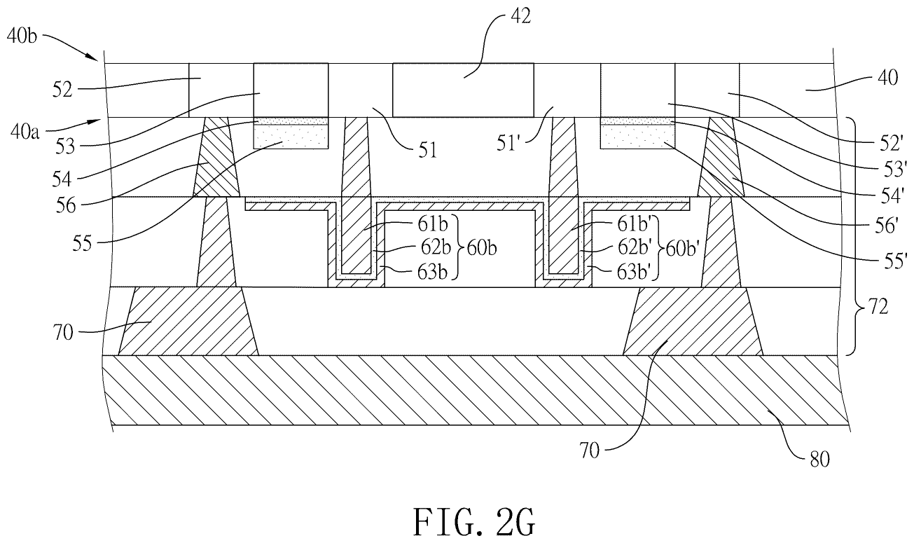

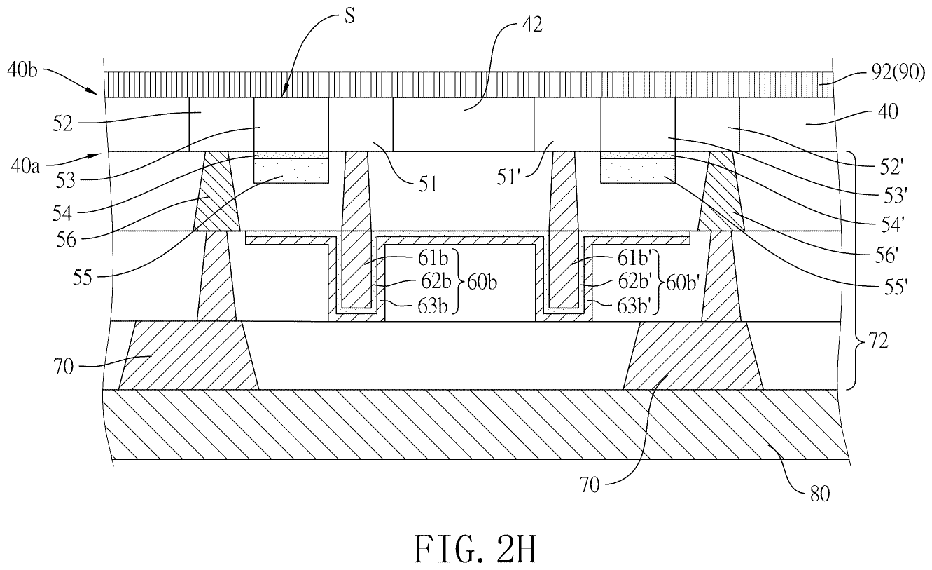

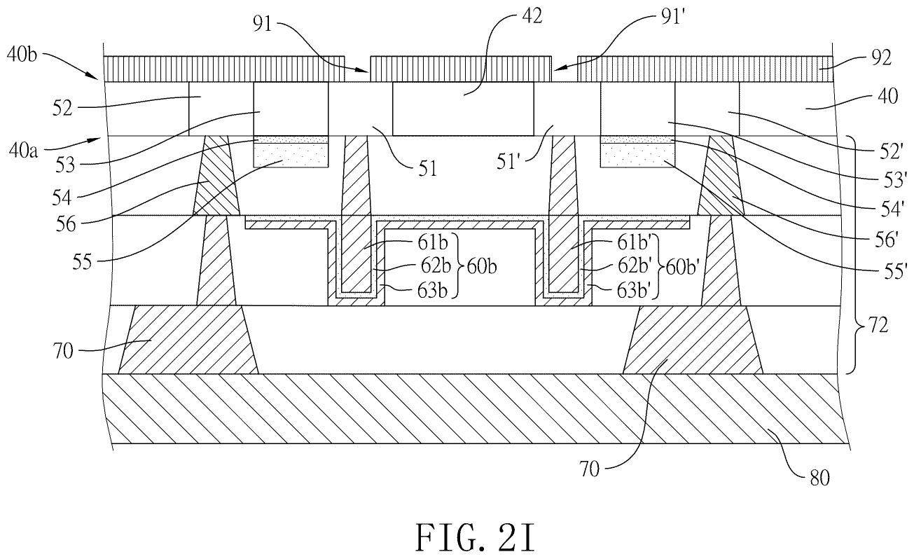

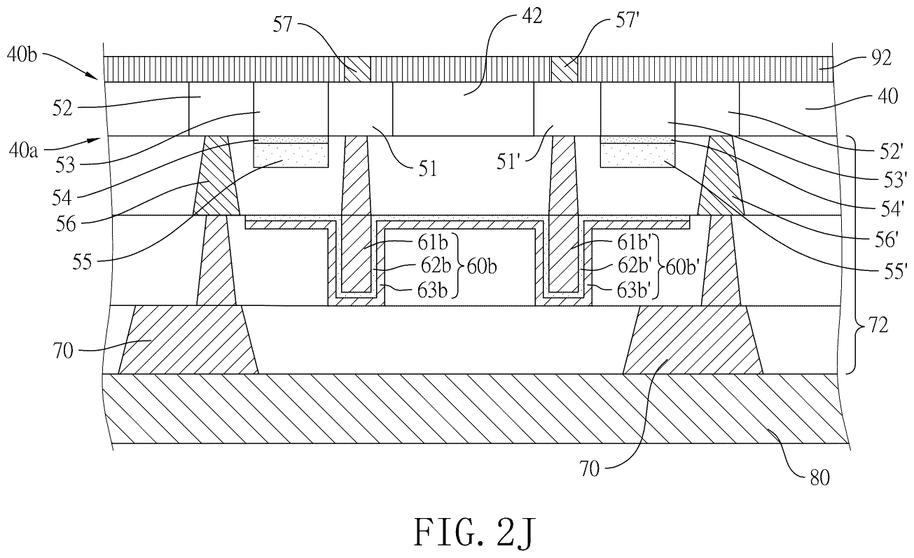

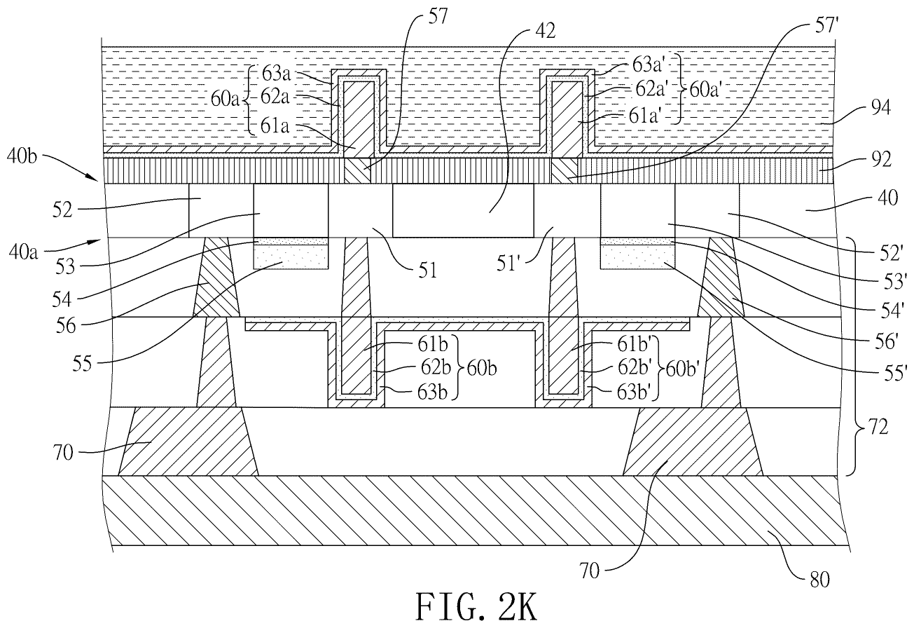

FIG. 2A to 2K are schematic diagrams illustrating intermediate stages in the manufacture of a semiconductor structure similar to the semiconductor structure as shown in FIG. 1 where like reference numerals indicate like elements.

As shown in FIG. 2A, a semiconductor substrate A1 is provided (step (a)). The semiconductor substrate A1 comprises a first substrate 10, a second substrate 40 on the first substrate 10, a bonding layer 20 between the first substrate 10 and the second substrate 40. In the embodiment shown in FIG. 2A, the semiconductor substrate A1 further comprises an etch stop layer 30 between the bonding layer 20 and the second substrate 40.

In one embodiment, each of the first substrate 10 and the second substrate 40 is a wafer with a diameter of 6, 8, 12, or 18 inches. In this situation, the first substrate 10 may be referred to as a handle wafer and the second substrate 40 may be referred to as a device wafer. The first substrate 10 and the second substrate 40 may each be a single crystalline semiconductor substrate, for example, made of silicon, germanium, silicon germanium, gallium arsenide (GaAs), indium phosphide (InP), silicon carbide (SiC), or gallium nitride (GaN). In other embodiments, the first substrate 10 may comprise glass, polysilicon, or ceramic. In one embodiment, the thickness of the second substrate 40 may be in a range from 5 nm and 0.2 μm. These values are merely examples and are not intended to be limiting.

The etch stop layer 30 has high etch selectivity against the bonding layer 20. An etch selectivity of the etch stop layer 30 against the bonding layer 20 may refer to the ratio of the etch rate of the bonding layer 20 to the etch rate of the etch stop layer 30 under the same etching condition, and the etch stop layer 30 may have a high etch selectivity against the bonding layer 20 when the etch rate of the bonding layer 20 is substantially faster than the etch rate of the etch stop layer 30 under the same etching condition. In some embodiments, the etch selectivity of the etch stop layer 30 against the bonding layer 20 may be higher than 5:1, 10:1, 20:1, 30:1, 50:1, 80:1, 100:1, 200:1, or 300:1. The etching process can be a dry etching process or a wet etching process depending on the materials of the etch stop layer 30 and the bonding layer 20.

For example, in one embodiment, when the etch stop layer 30 comprises silicon nitride and the bonding layer 20 comprises silicon oxide, wet etching can be performed using dilute HF (e.g., a weight ratio of H₂O to HF at about 100:1) as an etchants, an etch rate of the etch stop layer 30 may be about 1 Å/min, and an etch rate of the bonding layer 20 may be about 30 Å/min, which renders an etch selectivity of about 30:1 (oxide/nitride). In another embodiment, when the etch stop layer 30 comprises silicon oxynitride and the bonding layer 20 comprises silicon oxide, wet etching can be performed using buffered hydrofluoric acid (e.g., a solution of 6.6% HF (weight percentage) and 35.7% NH₄F (weight percentage) in water) as an etchant, an etch rate of the etch stop layer 30 may be about 24.5 nm/min, and an etch rate of the bonding layer 20 may be about 305.7 nm/min, which renders an etch selectivity of about 12.5:1 (oxide/oxynitride). The present disclosure is not limited thereto. Proper materials of the etch stop layer 30 and the bonding layer 20 and proper etching conditions can be selected based on actual needs and properties of the materials. For example, materials of the etch stop layer 30 and the bonding layer 20 may be selected such that the etch stop layer 30 may function as an etch stop layer with a higher etch selectivity against the bonding layer and/or may function as an etch stop layer under more desirable etch conditions.

In some embodiments, the bonding layer 20 comprises oxide such as silicon oxide, and the etch stop layer 30 may comprise silicon nitride, silicon oxynitride, doped semiconductor material, undoped semiconductor material, metal, conductive metal compound, or a combination thereof. The doped semiconductor material may be semiconductor material with p-type dopants, such as boron, aluminum, gallium, indium, the like, or combinations thereof, or semiconductor material with n-type dopants, such as phosphorus, arsenic, antimony, bismuth, the like, or combinations thereof. The undoped semiconductor material may be amorphous silicon, polysilicon, or silicon germanium, the like, or combinations thereof. In one embodiment, the thickness of the bonding layer 20 may be in a range between 0.2 nm and 1000 nm. In one embodiment, the thickness of the etch stop layer 30 may be in a range between 0.2 nm and 5 nm. However, the present disclosure is not limited thereto. In some embodiments, the thickness of the etch stop layer 30 may be in a range between 0.2 nm and 700 nm, for example, between 2 nm and 700 nm. These values are merely examples and are not intended to be limiting. In some embodiments, the etch stop layer 30 may be formed on a substrate (not shown) including the second substrate 40 by epitaxial growth or by deposition such as CVD, PVD, or ALD, and the substrate may be bonded onto the first substrate 10 by the bonding layer 20 after the formation of the etch stop layer 30. In some embodiments, a portion of the substrate may be removed after bonding, and the second substrate 40 is remained in the semiconductor substrate A1. The semiconductor substrate including an etch stop layer may be fabricated through bonding two substrates and related processes, as described in application No. PCT/US23/69597, the contents of which are incorporated herein by reference.

As shown in FIG. 2B, the isolation structure 42 may be formed in the second substrate 40 (step (g)). The isolation structure 42 may be a shallow trench isolation (STI) structure. The isolation structure 42 may comprise similar material(s) as described above with regard to FIG. 1 and may be formed by any suitable method(s). For example, the second substrate 40 may be etched through, forming a trench (not shown) exposing the etch stop layer 30, and dielectric material from which the isolation structure 42 is formed may then be deposited in the trench. Planarization process may also be performed.

As shown in FIG. 2C, the first source region 51, the second source region 51′, the first drain region 52 and the second drain region 52′ are formed in the second substrate 40, the first gate structure 55 and the first gate dielectric 54 are formed on the first side 40a of the second substrate 40, and the second gate structure 55′ and the second gate dielectric 54′ are formed on the first side 40a of the second substrate 40 (step (b)). In the embodiment shown in FIG. 2C, the first source region 51, the first drain region 52, the first body region 53, the first gate dielectric 54 and the first gate structure 55 may function as a first transistor and may be formed by any suitable method; the second source region 51′, the second drain region 52′, the second body region 53′, the second gate dielectric 54′ and the second gate structure 55′ may function as a second transistor and may be formed by any suitable method. In one embodiment, the first source region 51, the second source region 51′, the first drain region 52, and the second drain region 52′ may be formed by doping the second substrate 40. In one embodiment, a portion of the second substrate 40 may be etched, and a succeeding epitaxy process may be performed to form the first source region 51, the second source region 51′, the first drain region 52, and the second drain region 52′. In the embodiment shown in FIG. 2C, the doping process or the etching process is performed in a way that the first source region 51, the second source region 51′, the first drain region 52, and the second drain region 52′ can be formed extending through the thickness of the second substrate 40 and in contact with the etch stop layer 30. The first gate dielectric 54 and the second gate dielectric 54′ may be formed by forming a gate dielectric layer (not shown) on the first side 40a of the second substrate 40 by thermal oxidation, deposition such as CVD, PVD, ALD, any suitable method, and/or combinations thereof. The first gate structure 55 and the second gate structure 55′ may be formed by forming a gate conductor layer (not shown) on the gate dielectric layer by epitaxial growth, deposition such as CVD, PVD, or ALD, any suitable method, and/or combinations thereof. The first source region 51, the second source region 51′, the first drain region 52, and the second drain region 52′ may be formed before or after the formation of the gate dielectric layer and the gate conductor layer. In some embodiments, a subsequent gate replacement process can also be implemented. As shown in FIG. 2C, a bottom surface BS3 of the isolation structure 42 is level with bottom surfaces BS1 and BS2 of the second substrate 40 in the first cell region 50 and the second cell region 50′.

As shown in FIG. 2D, the third capacitor 60b and the fourth capacitor 60b′ are formed on the first side 40a of the second substrate 40. The third capacitor 60b and the fourth capacitor 60b′ can be formed by any suitable method, which may comprise photolithography, etching process, deposition process (e.g., PVD, CVD, ALD, or the like), and/or other applicable process. For example, the first electrodes 61b and 61b′, the capacitor dielectric 62b and 62b′, and the second electrodes 63b and 63b′ of the third capacitor 60b and the fourth capacitor 60b′ may be deposited on the first side 40a of the second substrate 40. In some embodiments, the first electrode 61b of the third capacitor 60b and the first electrode 61b′ of the fourth capacitor 60b′ may be deposited in a trench formed in one or more dielectric layer(s) disposed on the first side 40a of the second substrate 40. In some embodiments, the trench may be formed by photolithographic patterning and selective anisotropic dry etching.

The dielectric layers 72 may be formed on the first side 40a of the second substrate 40 by deposition process such as CVD, PVD, or ALD, spin-on process, and/or any suitable method. In some embodiments, the third capacitor 60b and the fourth capacitor 60b′ may be formed in one or more dielectric layer(s) of the dielectric layers 72. The first drain contact structure 56, the second drain contact structure 56′, and the interconnect structures 70 are formed in the dielectric layers 72 using any suitable method such as damascene and dual damascene process.

As shown in FIG. 2E, a third substrate 80 is added on the first side 40a of the second substrate 40, wherein the second substrate 40 is between the third substrate 80 and the first substrate 10 (step (c)). In some embodiments, the third substrate 80 is a wafer with a diameter of 6, 8, 12, or 18 inches. The third substrate 80 may be a handle wafer or a device wafer. In some embodiments, the third substrate 80 may comprise glass, polysilicon, or ceramic. In other embodiments, the third substrate 80 may be a single crystalline semiconductor substrate, for example, made of silicon, germanium, silicon germanium, gallium arsenide (GaAs), indium phosphide (InP), silicon carbide (SiC), or gallium nitride (GaN). The third substrate 80 may comprise an electronic device including but not limited to a transistor, a diode, a capacitor, and/or a resistor. In some embodiments, the device(s) in the third substrate 80 (not shown) may be electrically coupled to the interconnect structures 70. In one embodiment, the thickness of the third substrate 80 may be in a range between 20 μm and 700 μm. These values are merely examples and are not intended to be limiting. The third substrate 80 may provide mechanical support to the semiconductor structure to avoid damage to the devices or structures therein when the semiconductor structure undergoes subsequent processes. In one embodiment, the third substrate 80 can be formed by epitaxial growth, CVD, or PVD. In another embodiment, the third substrate 80 may be bonded onto the second substrate 40 by performing suitable process(es) such as adhesive bonding or direct bonding.

As shown in FIG. 2F, the first substrate 10 and the bonding layer 20 are removed (step (d)). The first substrate 10 and the bonding layer 20 can be removed by performing suitable process(es) such as grinding, chemical mechanical polishing (CMP), and etching process. The etching process may be isotropic etching or anisotropic etching, such as oxide etching, plasma etching, hydrogen peroxide etching, or the like. In one embodiment, the first substrate 10 is removed by grinding and/or CMP process, and the bonding layer 20 comprising oxide (e.g., silicon oxide) can be removed by applying a first etchant, e.g., dilute HF, buffered hydrofluoric acid, as previously described. It should be noted that the etchant and etching condition may be adjusted according to actual applications, and the disclosure is not limited thereto. In the embodiment shown in FIG. 2F, the etch stop layer 30 is exposed after the removal of the first substrate 10 and the bonding layer 20 due to its etch selectivity against the bonding layer 20. In one embodiment, the bonding layer 20 is completely removed without using a mask, which may reduce manufacturing costs and fabrication time.

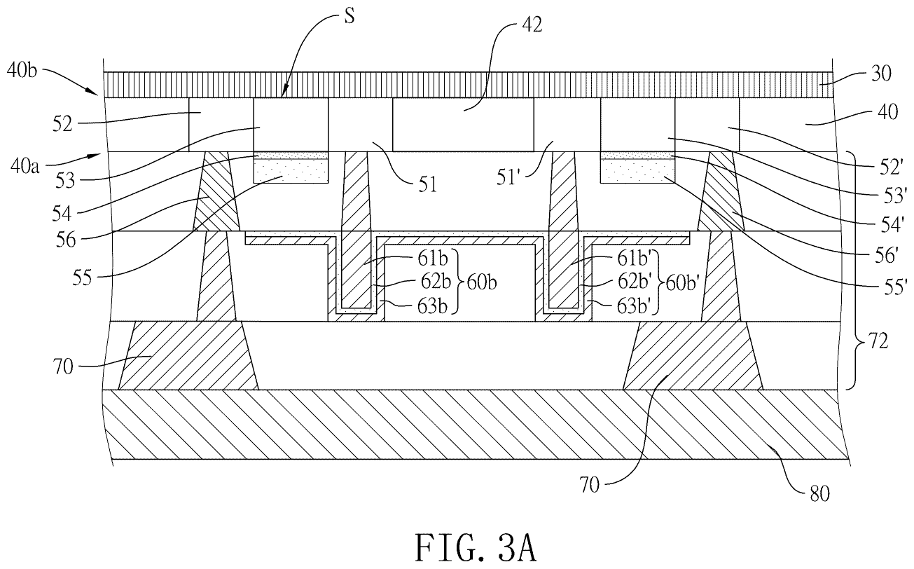

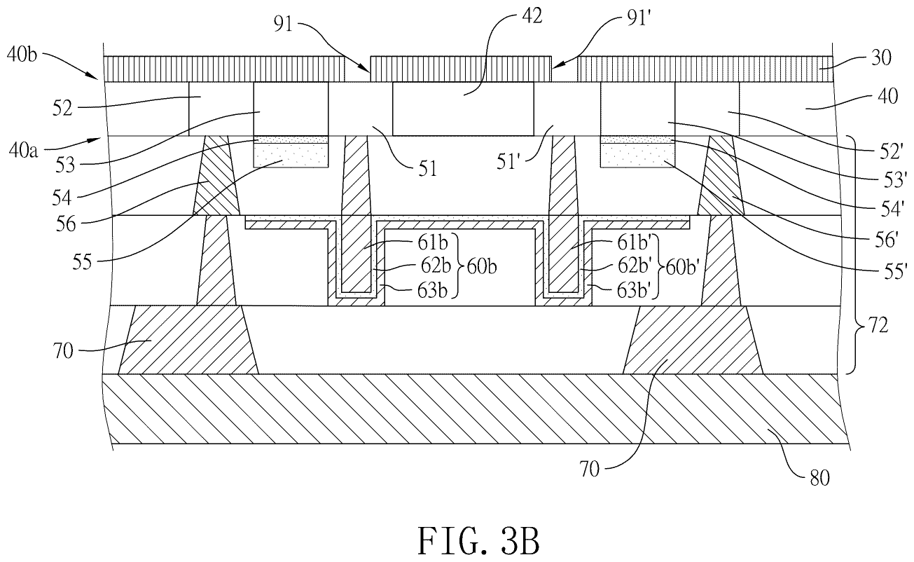

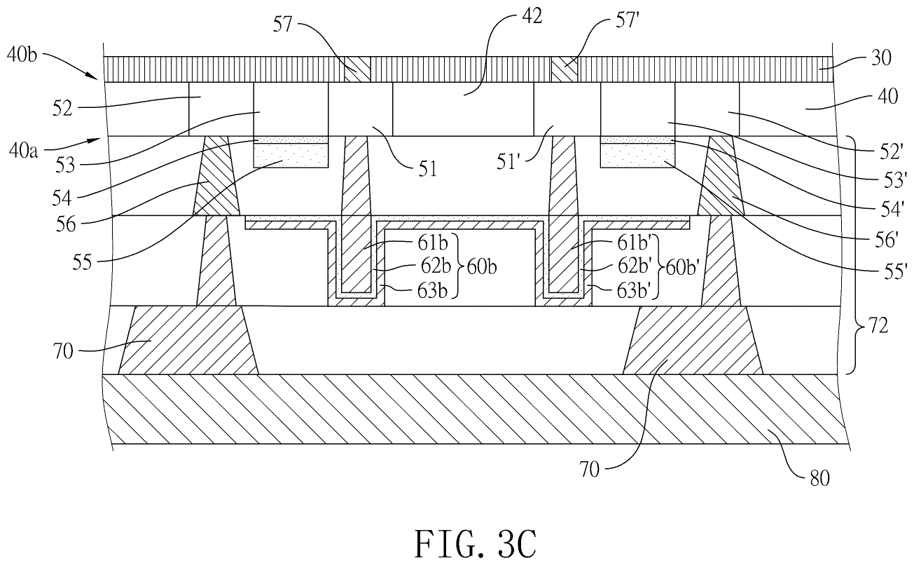

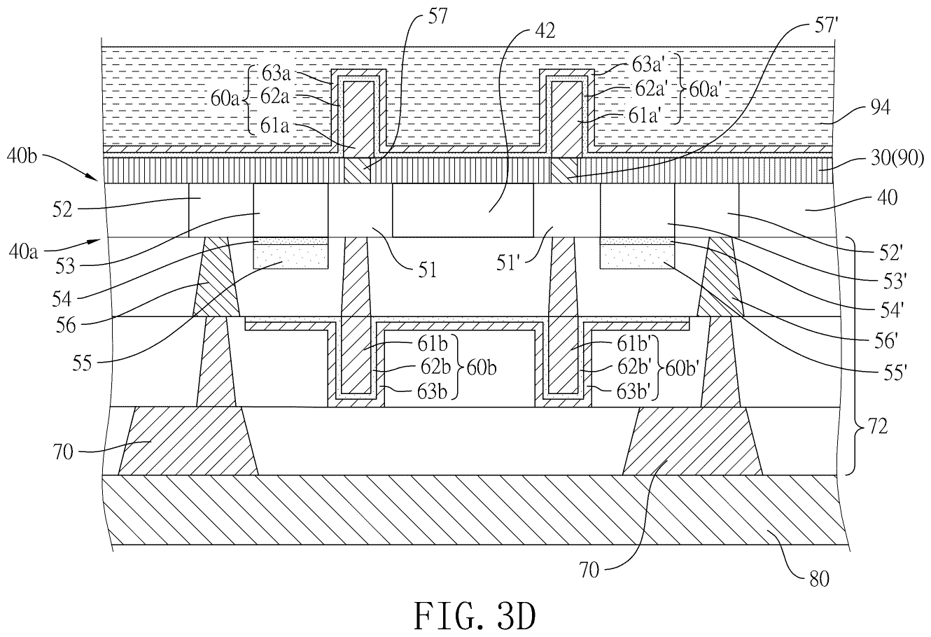

As shown in FIG. 2G, at least a portion of the etch stop layer 30 is removed (step (f)). The etch stop layer 30 can be removed by etching process such as oxide etching, plasma etching, hydrogen peroxide etching, or the like. The etching process may be isotropic or anisotropic. In one embodiment, the etch stop layer 30 comprises silicon nitride, and removing the etch stop layer 30 includes etching the etch stop layer 30 by a second etchant, e.g., hot phosphoric acid. However, the disclosure is not limited thereto. At least a portion of the second substrate 40 is exposed after step (f). In the embodiment shown in FIG. 2G, the etch stop layer 30 is completely removed. The etching process can be performed without using a mask. In other embodiments (as described below in greater detail with respect to FIG. 3B), only a portion of the etch stop layer 30 is removed by suitable methods, for example, photolithography and etching process.

As shown in FIG. 2H, a deposited dielectric layer 92 is formed on the second side 40b of the second substrate 40 as the first dielectric layer 90. The deposited dielectric layer 92 may comprise one or more layers of dielectric material such as silicon oxide, silicon oxynitride, low-k dielectric material, a combination thereof, and/or other applicable material, and can be formed by deposition process such as PVD, CVD, or ALD, spin-on process, or any applicable process.

The etch stop layer 30 can protect the second side 40b of the first transistor, the second transistor and the isolation structure from the etching process of the bonding layer 20. This may prevent defects occurred in the first transistor, the second transistor and the isolation structure during the etching process, especially when the second substrate 40 is thin. The exposed surface of the second substrate 40 after the removal of the etch stop layer 30 may have a better flatness, and thus a flat interface S extending from between the deposited dielectric layer 92 and the first cell region 50 to between the deposited dielectric layer 92 and the second cell region 50′ may be formed after the deposition of the dielectric layer 92. In some embodiments, the flat interface S has a flatness less than 2 μm and a smoothness less than 2 nm. However, the disclosure is not limited thereto. Also, by methods disclosed herein, the thickness of the second substrate (and the cell regions therein) can be easily controlled. The thickness of the second substrate across numerous cell regions within the same wafer on which the cells are manufactured may be more uniform. As such, the cells may have less defects in the transistors, and less variation in thickness and/or transistor's electrical characteristics (such as threshold voltage) across cells may be achieved. Moreover, the etch stop layer 30 may protect the isolation structure 42 during the etching process, such that the isolation structure 42 may remain intact and may be able to perform good electrical isolation between cells.

As shown in FIG. 2I, a first opening 91 and a second opening 91′ extending through the deposited dielectric layer 92 are formed to expose the first source region 51 and the second source region 51′, respectively. Portions of the dielectric layer 92 may be removed using an etching process through openings of a patterned mask layer (not shown) to form the first opening 91 and the second opening 91′. Afterwards, the patterned mask layer is removed.

As shown in FIG. 2J, the first contact structure 57 and the second contact structure 57′ are formed in the first opening 91 and the second opening 91′, respectively. The first contact structure 57 and the second contact structure 57′ may each comprise metal, doped semiconductor material, or conductive metal compound. The first contact structure 57 and the second contact structure 57′ may be made through deposition process such as CVD, PVD, ALD, damascene, or dual damascene, or any applicable method.

By methods disclosed herein, the deposited dielectric layer 92 may be formed in direct contact with the first source region 51 and the second source region 51′ without residual bonding layer and other portion of semiconductor layer therebetween. Therefore, during the formation of the opening, it may be easier to control the end point of the etching process to expose the source region, such that the openings can be formed to expose the source region while over-etching of the source region may be prevented, thus it may be easier to form contact structures physically and electrically connected to respective source region in each of the plurality of cells. The dielectric layer (e.g., dielectric layer 92) which provides electrical isolation between adjacent contact structures may also be easier to be formed, and distance between two contact structures can shrink to 1 F to 2.5 F, and the cell size can be decreased.

As shown in FIG. 2K, the first capacitor 60a and the second capacitor 60a′ are formed on the second side 40b of the second substrate 40 (step (e)). The first capacitor 60a may be formed electrically connected to the first contact structure 57, and the second capacitor 60a′ may be formed electrically connected to the second contact structure 57′. Therefore, the first capacitor 60a is electrically connected to the first source region 51, and the second capacitor 60a′ is electrically connected to the second source region 51′. The first capacitor 60a and the second capacitor 60a′ may be formed by any suitable methods, which may comprise photolithography, etching process, deposition process (e.g., PVD, CVD, ALD, or the like), and/or other applicable process. For example, the first capacitor 60a and the second capacitor 60a′ may be formed by methods similar to those of the third capacitor 60b and the fourth capacitor 60b′ described above with reference to FIG. 2D. In one embodiment, the first contact structure 57 and the first electrode 61a of the first capacitor 60a may be formed by the same material, and the second contact structure 57′ and the first electrode 61a′ of the second capacitor 60a′ may be formed by the same material. In one embodiment, instead of forming the first contact structure 57 and the second contact structure 57′ in separate process(es) as shown in FIG. 2J, the first contact structure 57 and the first electrode 61a of the first capacitor 60a may be formed integrally, and the second contact structure 57′ and the first electrode 61a′ of the second capacitor 60a′ may be formed integrally. A second dielectric layer 94 may also be formed on the second side 40b of the second substrate 40 and over the deposited dielectric layer 92 by suitable process(es) such as deposition process such as PVD, CVD, or ALD, spin-on process, and/or any applicable method.

By methods disclosed herein, the fabrication of capacitors on the second side can become more easier. Moreover, it may be easier to form capacitors with a larger size and/or favorable configuration (e.g., favorable shape of the electrodes) on the “opened” second side of the substrate. In addition, forming capacitors on both sides of a transistor may increase the cell capacitance.

FIG. 3A to 3D are schematic diagrams illustrating intermediate stages in the manufacture of a semiconductor structure similar to the semiconductor structure as shown in FIG. 1 where like reference numerals indicate like elements. The semiconductor structure shown in FIG. 3A may be formed using a method similar to that described above with reference to FIGS. 2A-2F and the description is not repeated herein. The etch stop layer 30 can protect the second side 40b of the first transistor, the second transistor and the isolation structure from the etching process of the bonding layer 20. Since the etch stop layer 30 may be formed on a substrate including the second substrate 40 by epitaxial growth or by deposition such as CVD, PVD, or ALD, during the manufacture of the semiconductor substrate A1 shown in FIG. 2A, an interface S extending from between the etch stop layer 30 and the first cell region 50 to between the etch stop layer 30 and the second cell region 50′ may be flat. In some embodiments, the flat interface S has a flatness less than 2 μm and a smoothness less than 2 nm. However, the disclosure is not limited thereto. As such, the cells may have less defects in the transistor, and less variation in thickness and/or transistor's electrical characteristics (such as threshold voltage) across cells may be achieved. The etch stop layer 30 may also protect the isolation structure 42 during the etching process, and therefore the isolation structure 42 may remain intact and may be able to perform good electrical isolation between cells.

As shown in FIG. 3B, a first opening 91 and a second opening 91′ extending through the etch stop layer 30 are formed to expose the second side 40b of the source region 51. Specifically, instead of completely removing the etch stop layer 30, only portions of the etch stop layer 30 may be removed using an etching process through openings of a patterned mask layer (not shown) to form the first opening 91 and the second opening 91′. For example, when the etch stop layer 30 comprises silicon nitride and the bonding layer 20, dry etching can be performed by remote plasma using NF₃ as an etching gas to remove only a portion of the etch stop layer 30.

As shown in FIG. 3C, the first contact structure 57 and the second contact structure 57′ are formed in the first opening 91 and the second opening 91′, respectively. In some embodiments, the formation methods of the first contact structure 57 and the second contact structure 57′ are similar to those described above with reference to FIG. 2J.

By methods disclosed herein, the etch stop layer 30 may be formed in direct contact with the first source region 51 and the second source region 51′ without other portion of semiconductor layer therebetween. Therefore, during the formation of the opening, it may be easier to control the end point of the etching process to expose the source region, such that the openings can be formed to expose the source region while over-etching of the source region may be prevented, thus it may be easier to form contact structures physically and electrically connected to respective source region in each of the plurality of cells. The etch stop layer 30 may also provide electrical isolation between adjacent contact structures, therefore, distance between two contact structures can shrink to 1 F to 2.5 F, and the cell size can be decreased.

As shown in FIG. 3D, the first capacitor 60a and the second capacitor 60a′ are formed on the second side 40b of the second substrate 40. The first capacitor 60a may be formed electrically connected to the first contact structure 57, and the second capacitor 60a′ may be formed electrically connected to the second contact structure 57′. Therefore, the first capacitor 60a is electrically connected to the first source region 51, and the second capacitor 60a′ is electrically connected to the second source region 51′. The second dielectric layer 94 may also be formed on the second side 40b of the second substrate 40 and over the etch stop layer 30. In some embodiments, the formation methods of the first capacitor 60a, the second capacitor 60a′, and the second dielectric layer 94 are similar to those described above with reference to FIG. 2K.

In the embodiment shown in FIG. 3D, the first dielectric layer 90 comprises the etch stop layer 30. The etch stop layer 30 may comprise silicon nitride or silicon oxynitride. In one embodiment, the thickness of the etch stop layer 30 may be in a range between 2 nm and 700 nm. These values are merely examples and are not intended to be limiting. In some other embodiments, another deposited dielectric layer (not shown) may be formed on the etch stop layer before the formation of the first opening and the second opening.

By methods disclosed herein, the fabrication of capacitors on the second side can become more easier. Moreover, it may be easier to form capacitors with a larger size and/or favorable configuration (e.g., favorable shape of the electrodes) on the “opened” second side of the substrate. In addition, forming capacitors on both sides of a transistor may increase the cell capacitance.

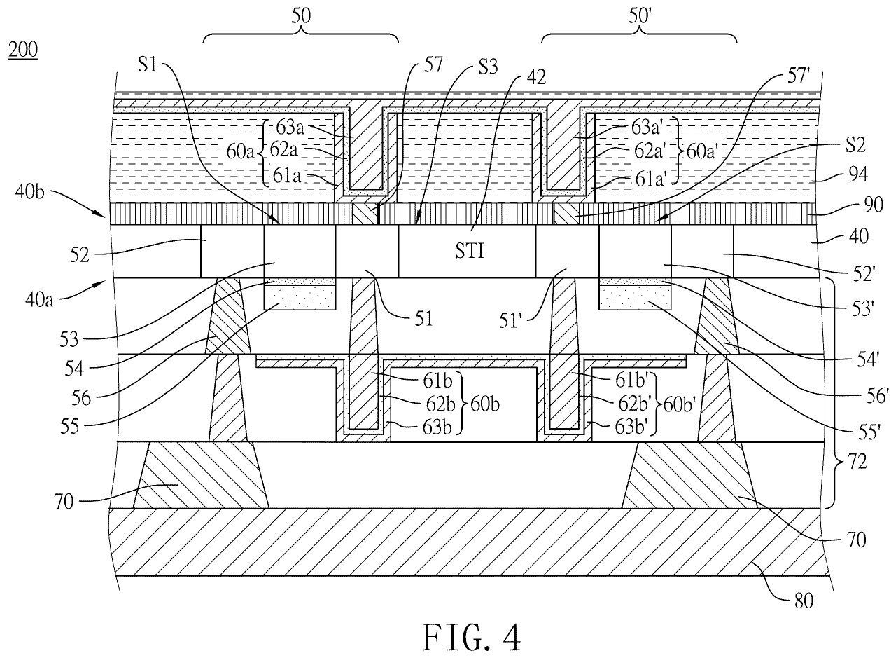

FIG. 4 is a schematic view to illustrate a semiconductor structure according to the present disclosure. Semiconductor structure 200 in FIG. 4 may be substantially similar to semiconductor structure 100 in FIG. 1 where like reference numerals indicate like elements. In this embodiment, each of the first electrode 61a of the first capacitor 60a and the first electrode 61a′ of the second capacitor 60a′ is container-shaped.

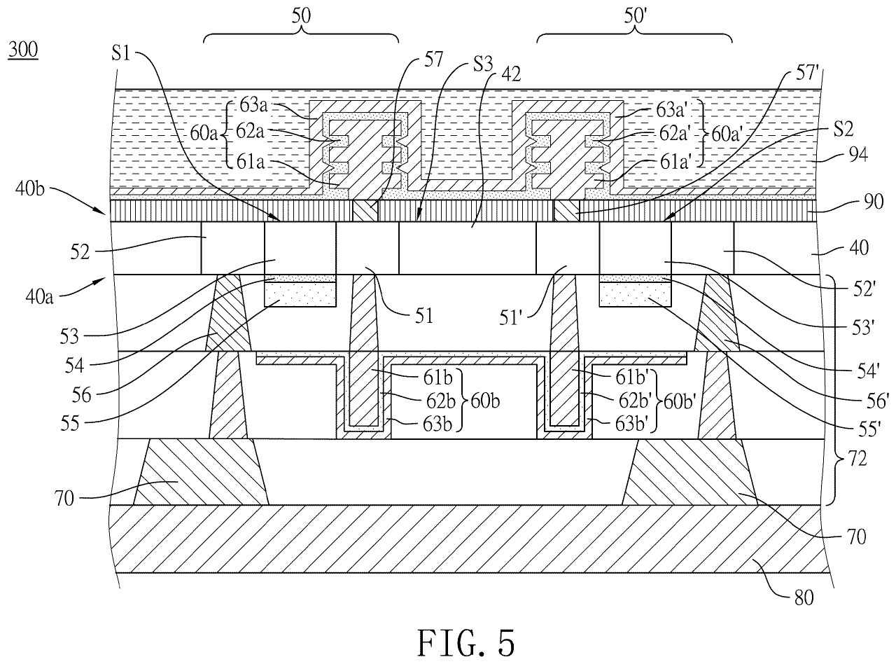

FIG. 5 is a schematic view to illustrate a semiconductor structure according to the present disclosure. Semiconductor structure 300 in FIG. 5 may be substantially similar to semiconductor structure 100 in FIG. 1 where like reference numerals indicate like elements. In this embodiment, each of the first electrode 61a of the first capacitor 60a and the first electrode 61a′ of the second capacitor 60a′ is multi-fin-shaped.

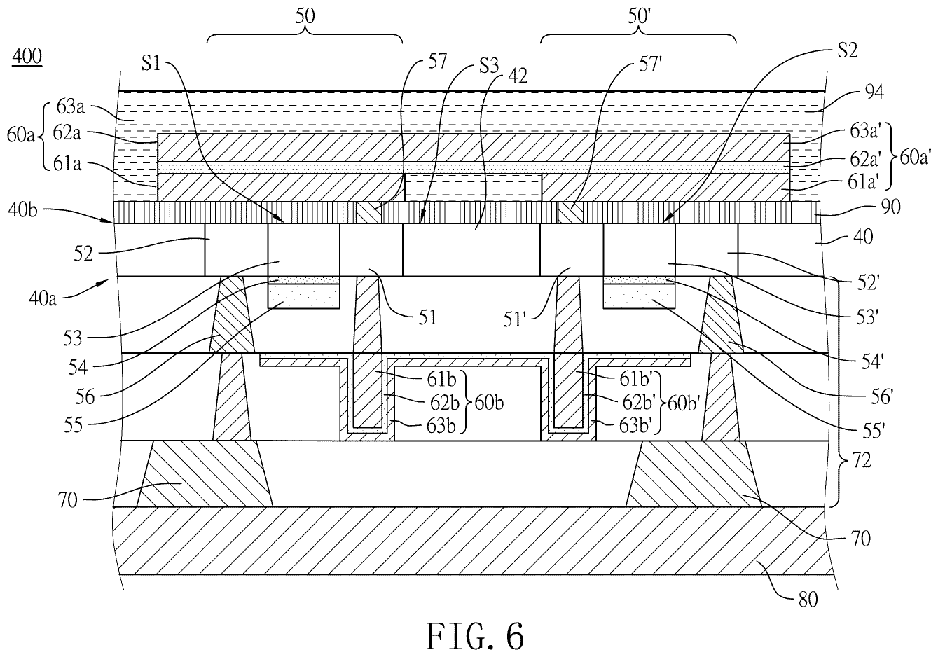

FIG. 6 is a schematic view to illustrate a semiconductor structure according to the present disclosure. Semiconductor structure 400 in FIG. 6 may be substantially similar to semiconductor structure 100 in FIG. 1 where like reference numerals indicate like elements. In this embodiment, each of the first electrode 61a of the first capacitor 60a and the first electrode 61a′ of the second capacitor 60a′ is plate-shaped.

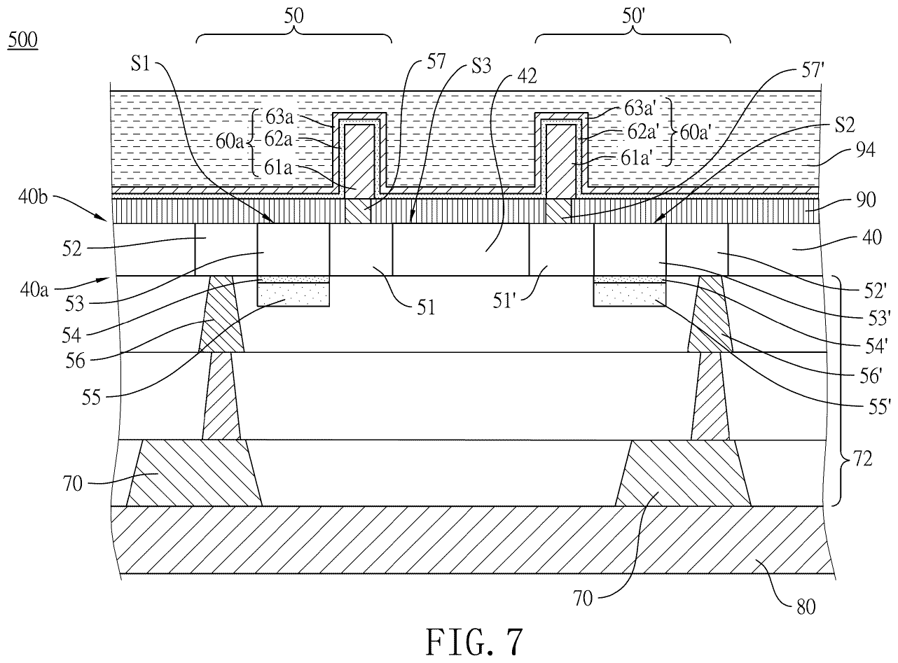

FIG. 7 is a schematic view to illustrate a semiconductor structure according to the present disclosure. Semiconductor structure 500 in FIG. 7 may be substantially similar to semiconductor structure 100 in FIG. 1 where like reference numerals indicate like elements. In this embodiment, the semiconductor structure 500 only comprises a first capacitor 60a and a second capacitor 60a′ on the second side 40b of the semiconductor layer 40 without a third capacitor and a fourth capacitor on the first side 40a of the semiconductor layer 40.

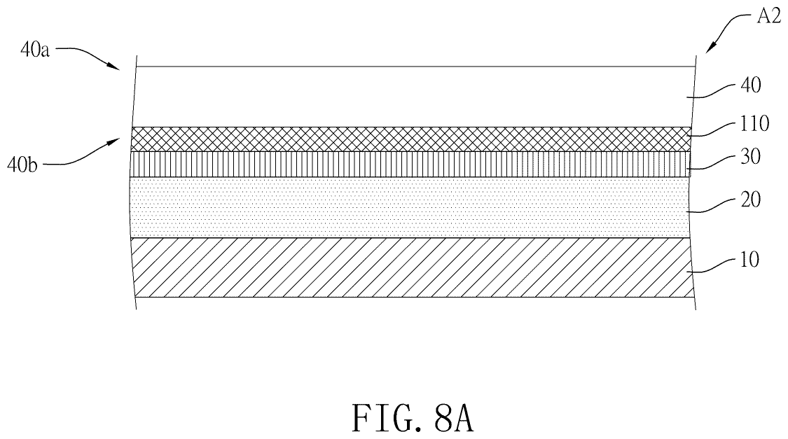

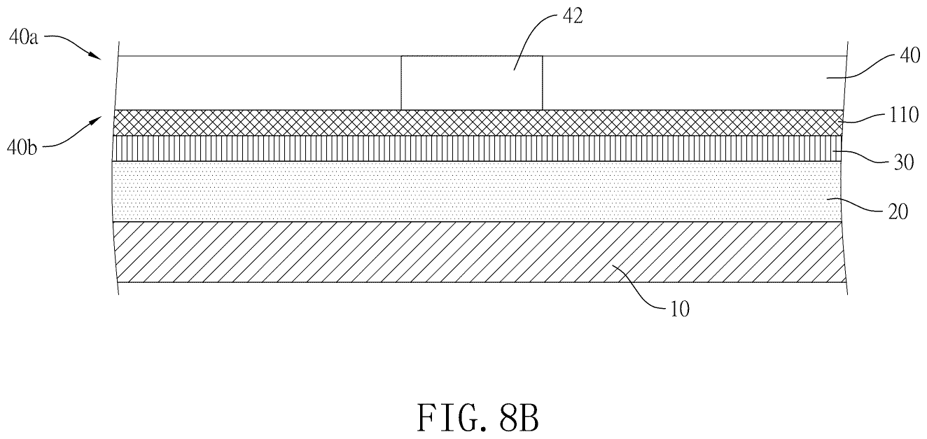

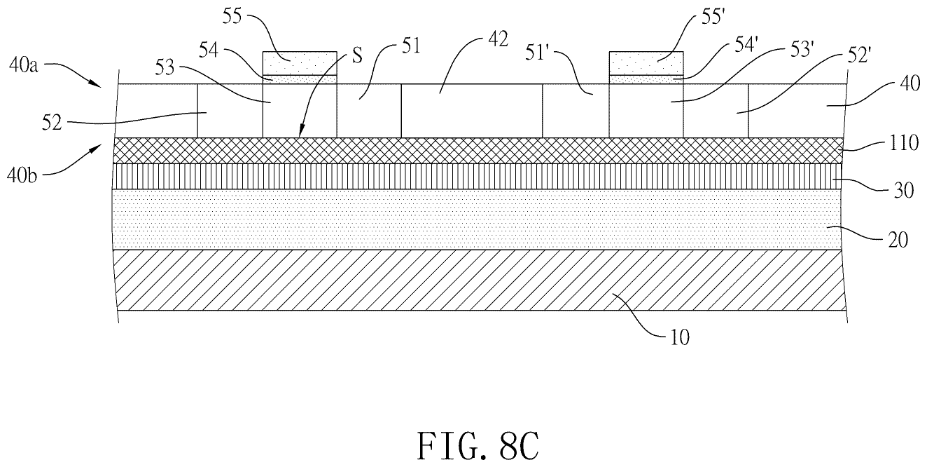

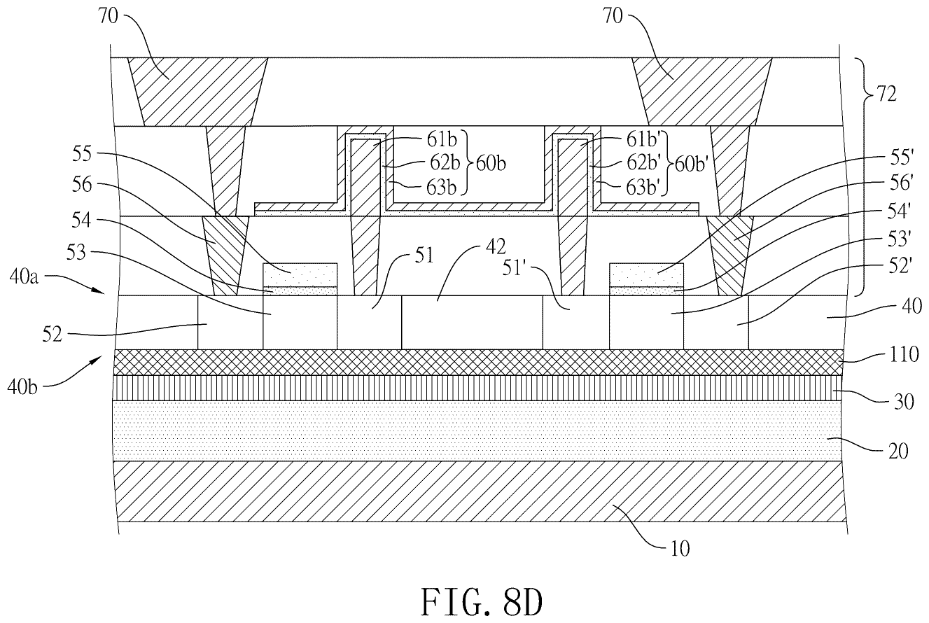

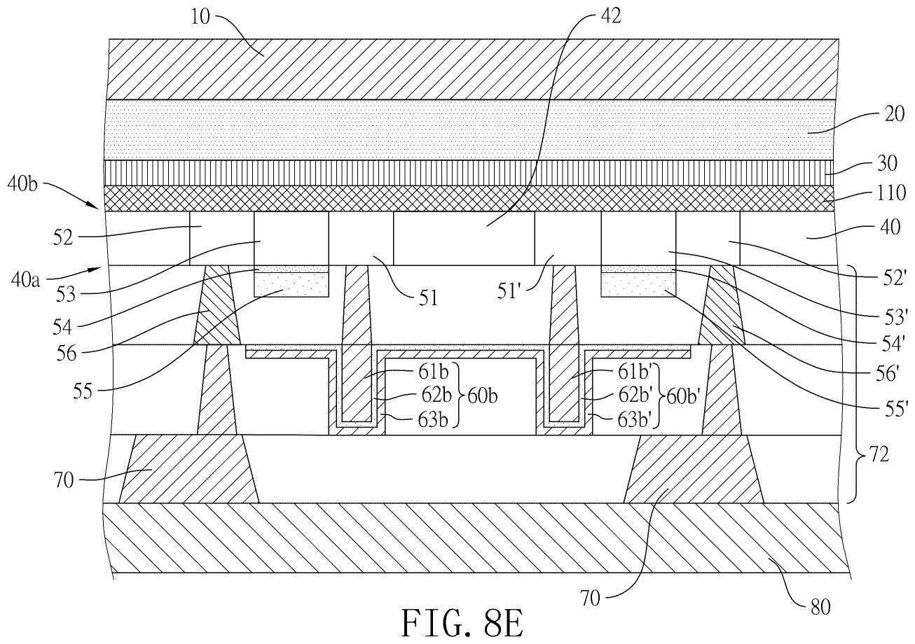

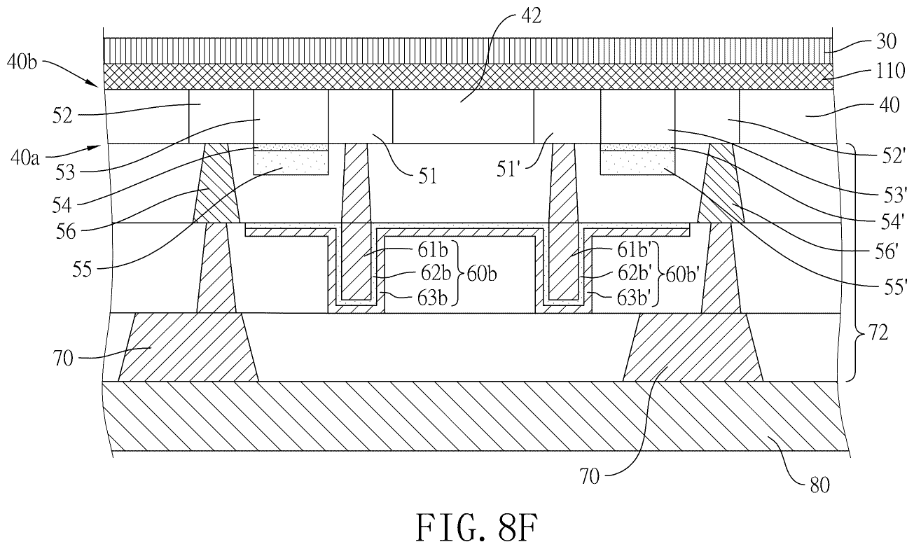

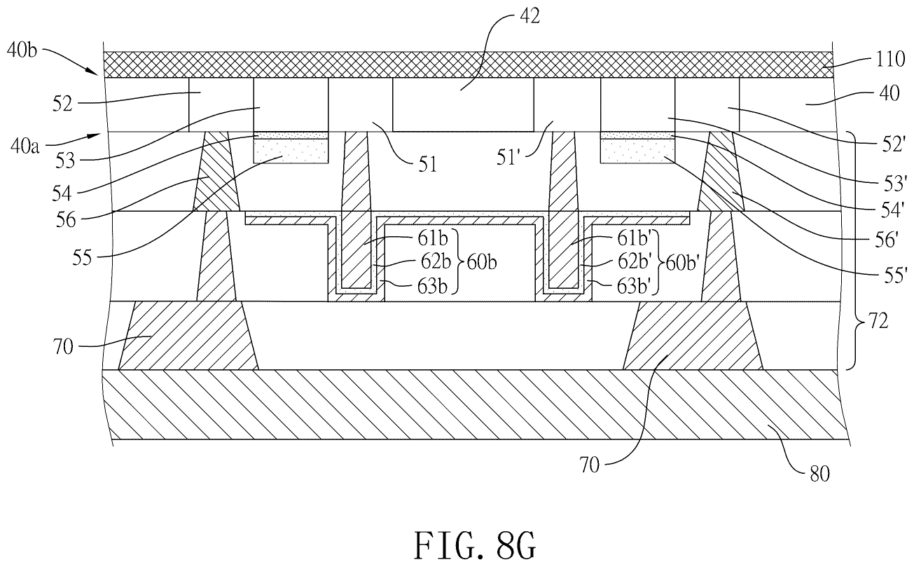

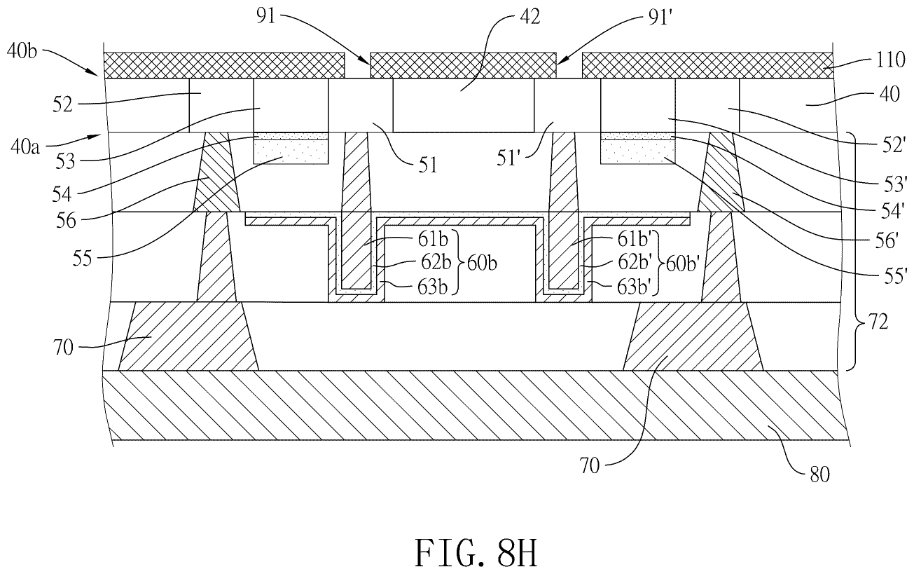

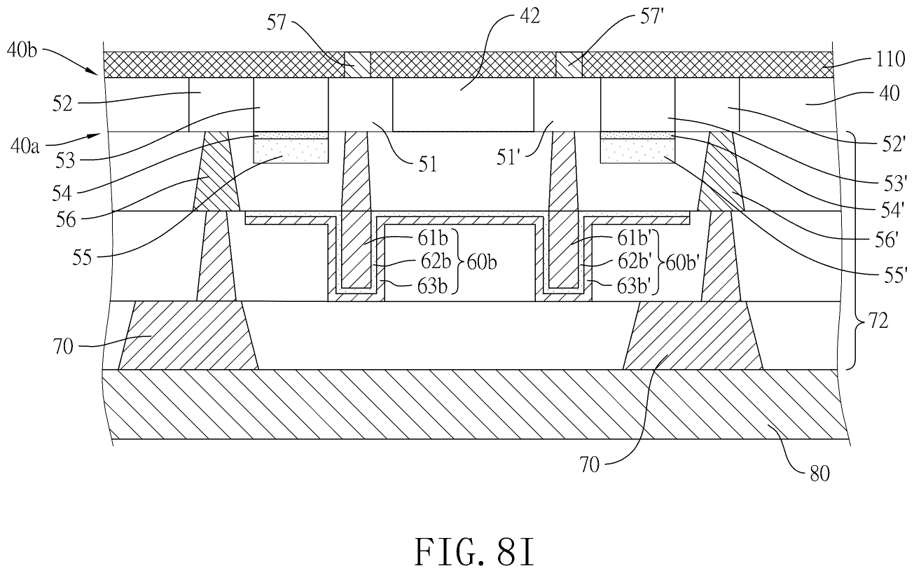

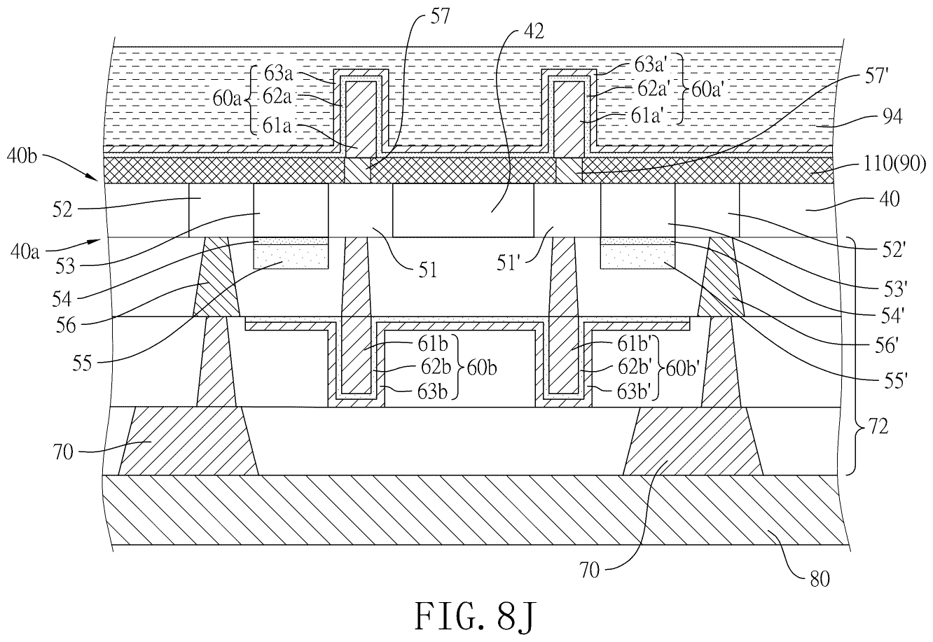

FIGS. 8A to 8J are schematic diagrams illustrating intermediate stages in the manufacture of a semiconductor structure similar to the semiconductor structure as shown in FIG. 1 according to one embodiment of the present disclosure.

As shown in FIG. 8A, a semiconductor substrate A2 is provided (step (a)). The semiconductor substrate A2 may be substantially similar to the semiconductor substrate A1 in FIG. 2A where like reference numerals indicate like elements. The semiconductor substrate A2 comprises a first substrate 10, a second substrate 40 on the first substrate 10, and a bonding layer 20 between the first substrate 10 and the second substrate 40. The semiconductor substrate A2 may further comprise an etch stop layer 30 and an intermediate layer 110, wherein the etch stop layer 30 is disposed between the bonding layer 20 and the second substrate 40, and the intermediate layer 110 is disposed between the etch stop layer 30 and the second substrate 40. In some embodiments, the bonding layer 20 comprises silicon oxide, and the etch stop layer 30 comprises silicon nitride. In some embodiments, the intermediate layer 110 may comprise one or more layers of dielectric material such as silicon oxide, silicon oxynitride, low-k dielectric material, a combination thereof, and/or other applicable material. Proper materials of the etch stop layer 30 and the intermediate layer 110 can be selected based on actual needs and properties of the materials. In one embodiment, the thickness of the intermediate layer 110 may be in a range between 2 nm and 700 nm, and the thickness of the etch stop layer 31 may be in a range between 0.2 nm and 5 nm. These values are merely examples and are not intended to be limiting. In some embodiments, the intermediate layer 110 and the etch stop layer 30 may be formed on a substrate (not shown) including the second substrate 40 by epitaxial growth or by deposition such as CVD, PVD, or ALD, and the substrate may be bonded onto the first substrate 10 by the bonding layer 20 after the formation of the intermediate layer 110 and the etch stop layer 30. In some embodiments, a portion of the substrate may be removed after bonding, and the second substrate 40 is remained in the semiconductor substrate A2. The semiconductor substrate including an etch stop layer and an intermediate layer may be fabricated through bonding two substrates and related processes, as described in application No. PCT/US23/69597, the contents of which are incorporated herein by reference. The related details about the first substrate 10, the bonding layer 20, the etch stop layer 30, and the second substrate 40 described above may also apply here.

As shown in FIG. 8B, the isolation structure 42 such as a shallow trench isolation (STI) may be formed in the second substrate 40 (step (g)). In some embodiments, the formation methods of the isolation structure 42 are similar to those described above with reference to FIG. 2B if applicable. In some embodiments, the second substrate 40 may be etched through, forming a trench (not shown) exposing the intermediate layer 110, and dielectric material from which the isolation structure 42 is formed may then be deposited in the trench.

As shown in FIG. 8C, the first source region 51, the second source region 51′, the first drain region 52, and the second drain region 52′ are formed in the second substrate 40, the first gate structure 55 and the first gate dielectric 54 are formed on the first side 40a of the second substrate 40, and the second gate structure 55′ and the second gate dielectric 54′ are formed on the first side 40a of the second substrate 40 (step (b)). In some embodiments, the formation methods of the first source region 51, the second source region 51′, the first drain region 52, the second drain region 52′, the first body region 53, the second body region 53′, the first gate dielectric 54, the second gate dielectric 54′, the first gate structure 55, and the gate structure 55′ are similar to those described above with reference to FIG. 2C. By methods disclosed herein, a flat interface S extending from between the intermediate layer 110 and the first cell region 50 to between the intermediate layer 110 and the second cell region 50′ may be formed. In some embodiments, the flat interface S has a flatness less than 2 μm and smoothness less than 2 nm. However, the disclosure is not limited thereto.

As shown in FIG. 8D, the third capacitor 60b and the fourth capacitor 60b′ are formed on the first side 40a of the second substrate 40. The dielectric layers 72 may be formed on the first side 40a of the second substrate 40. In some embodiments, the third capacitor 60b and the fourth capacitor 60b′ may be formed in one or more dielectric layer(s) of the dielectric layers 72. In some embodiments, the formation methods of the third capacitor 60b, the fourth capacitor 60b′, and the dielectric layers 72 are similar to those described above with reference to FIG. 2D. The first drain contact structure 56, the second drain contact structure 56′, and the interconnect structures 70 may be formed in the dielectric layers 72 using any suitable method such as damascene and dual damascene process.

As shown in FIG. 8E, a third substrate 80 is added on the first side 40a of the second substrate 40, wherein the second substrate 40 is located between the third substrate 80 and the first substrate 10 (step (c)). The third substrate 80 may be bonded to the second substrate 40 or formed on the second substrate 40 by process(es) similar to that described above with regard to FIG. 2E. The related details about the third substrate 80 described above may apply here if applicable.

As shown in FIG. 8F, the first substrate 10 and the bonding layer 20 are removed (step (d)). The first substrate 10 and the bonding layer 20 may be removed by process(es) similar to that described above with regard to FIG. 2F. In the embodiment shown in FIG. 8F, the bonding layer 20 is completely removed without using a mask. The related details about the removal of the first substrate 10 and the bonding layer 20 described above may apply here if applicable.

As shown in FIG. 8G, at least a portion of the etch stop layer 30 is removed to expose the intermediate layer 110 (step (f)). The etch stop layer 30 may be removed by process(es) similar to that described above with regard to FIG. 2G. In the embodiment shown in FIG. 8G, the etch stop layer 30 is completely removed, and the removal of etch stop layer 30 may be performed by etching process(es) without using a mask. It is also possible that only a portion of the etch stop layer 30 is removed. In one embodiment, the etch stop layer 30 comprises silicon nitride, and the intermediate layer 110 comprises silicon oxide. In this situation, removing the etch stop layer includes etching the etch stop layer 30 by a second etchant such as hot phosphoric acid. However, the disclosure is not limited thereto.

As shown in FIG. 8H, a first opening 91 and a second opening 91′ extending through the intermediate layer 110 are formed to expose the first source region 51 and the second source region 51′, respectively. The first opening 91 and the second opening 91′ may be formed by process(es) similar to that described above with regard to FIGS. 21 and 3B. For example, portions of the intermediate layer 110 may be removed using an etching process through openings of a patterned mask layer (not shown) to form the first opening 91 and the second opening 91′. Suitable etchant and etching condition may be selected according to actual applications

As shown in FIG. 8I, the first contact structure 57 and the second contact structure 57′ are formed in the first opening 91 and the second opening 91′, respectively. In some embodiments, the formation methods of the first contact structure 57 and the second contact structure 57′ are similar to those described above with reference to FIG. 2J.

By methods disclosed herein, the intermediate layer 110 may be formed in direct contact with the first source region 51 and the second source region 51′ without residual bonding layer and other portion of semiconductor layer therebetween. The etch stop layer 30 may protect the intermediate layer 110 during the etching process of the bonding layer 20, such that the intermediate layer 110 may remain intact and may be able to perform good electrical isolation between adjacent contact structures. Therefore, distance between two contact structures can shrink to 1 F to 2.5 F, and the cell size can be decreased. Also, as discussed above, since the structure shown in FIG. 8G provides an easier control of the end point of the etching process that forms openings extending through the intermediate layer, it may be easier to form contact structures physically and electrically connected to respective source region in each of the plurality of cells.

As shown in FIG. 8J, the first capacitor 60a and the second capacitor 60a′ are formed on the second side 40b of the second substrate 40. The first capacitor 60a may be formed electrically connected to the first contact structure 57, and the second capacitor 60a′ may be formed electrically connected to the second contact structure 57′. Therefore, the first capacitor 60a is electrically connected to the first source region 51, and the second capacitor 60a′ is electrically connected to the second source region 51′. The second dielectric layer 94 may also be formed on the second side 40b of the second substrate 40 and over the intermediate layer 110. In some embodiments, the formation methods of the first capacitor 60a, the second capacitor 60a′, and the second dielectric layer 94 are similar to those described above with reference to FIG. 2K.

In the embodiment shown in FIG. 8J, the first dielectric layer 90 comprises the intermediate layer 110. In one embodiment, the intermediate layer 110 may comprise silicon oxide or low-k dielectric material such as hydrogen silsesquioxane (HSQ), fluoride silicate glass (FSG), phosphosilicate glass (PSG), borophosphosilicate glass (BPSG), silicon carbon material, Spin-On-Glass, other suitable low-k dielectric materials, and a combination thereof. In some embodiments, the thickness of the intermediate layer 110 may be in a range between 2 nm and 700 nm. In some embodiments, the thickness of the intermediate layer 110 may be in a range between 2 nm and 30 nm. These values are merely examples and are not intended to be limiting.

By methods disclosed herein, the fabrication of capacitors on the second side can become more easier. Moreover, it may be easier to form capacitors with a larger size and/or favorable configuration (e.g., favorable shape of the electrodes) on the “opened” second side of the substrate. In addition, forming capacitors on both sides of a transistor may increase the cell capacitance.

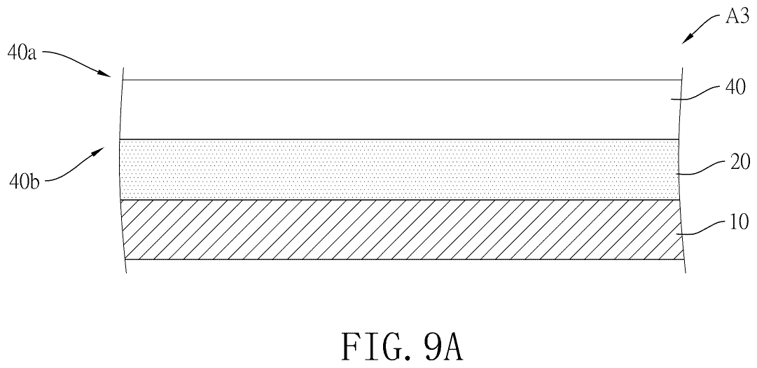

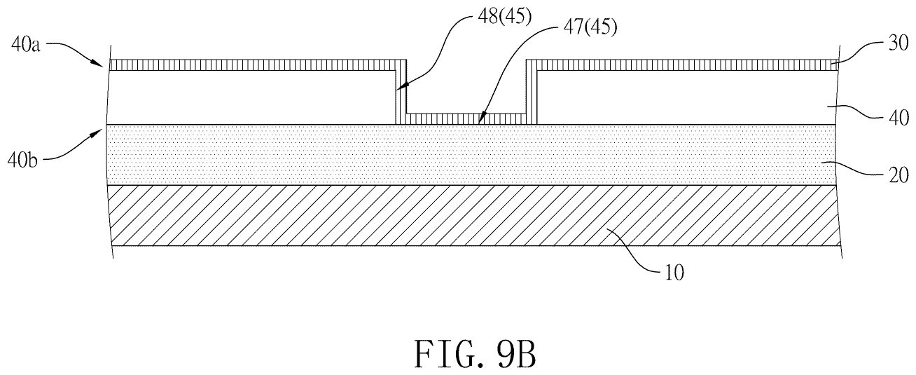

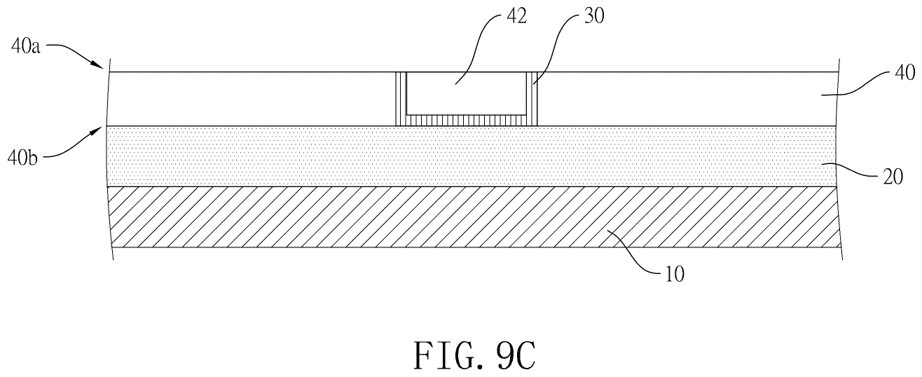

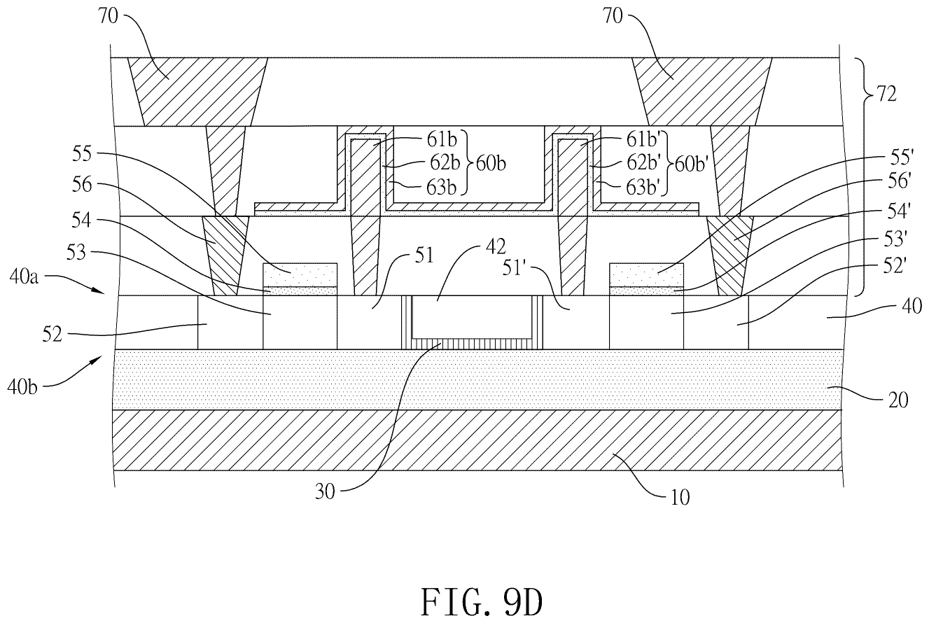

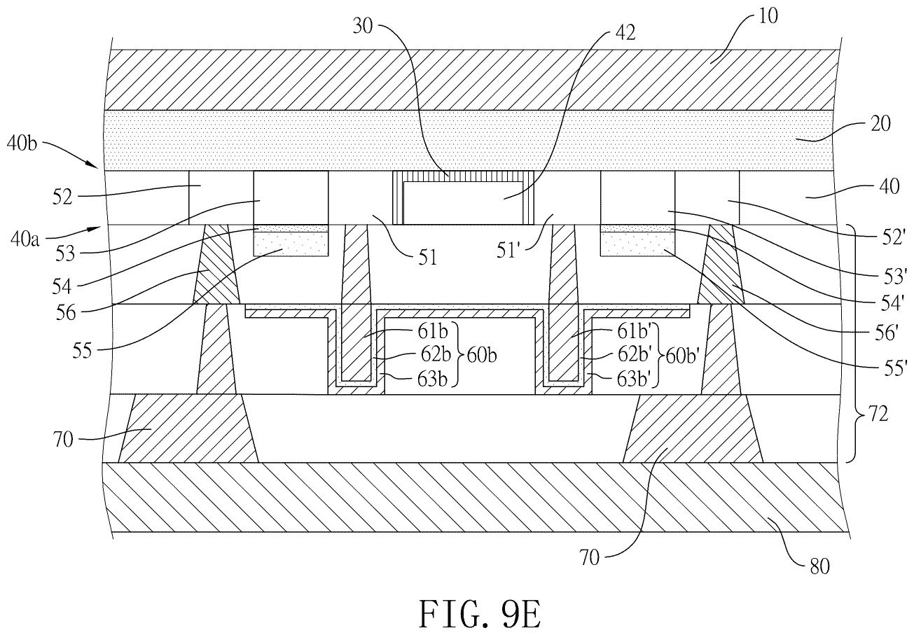

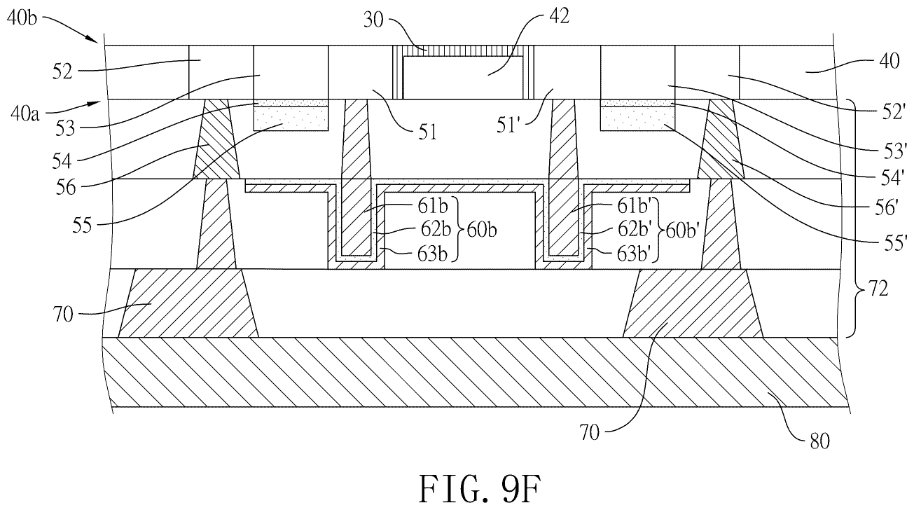

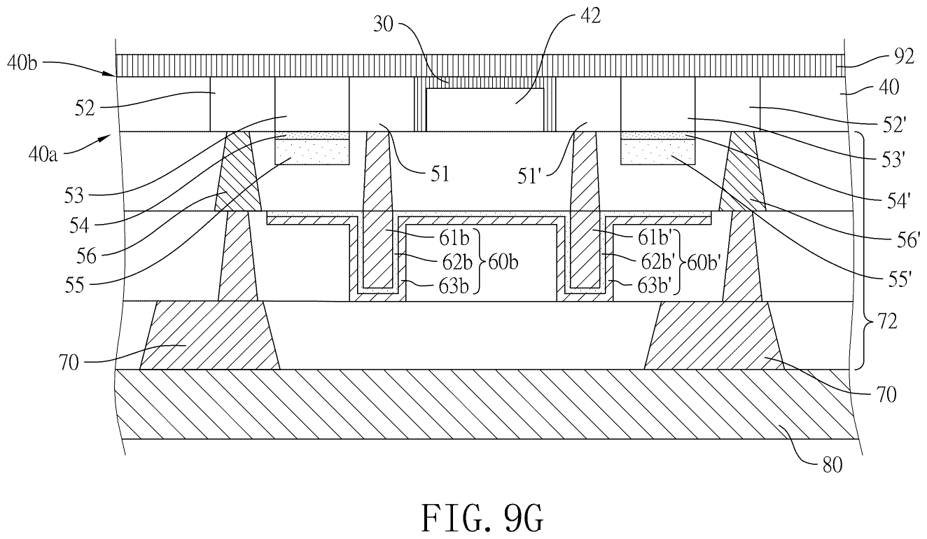

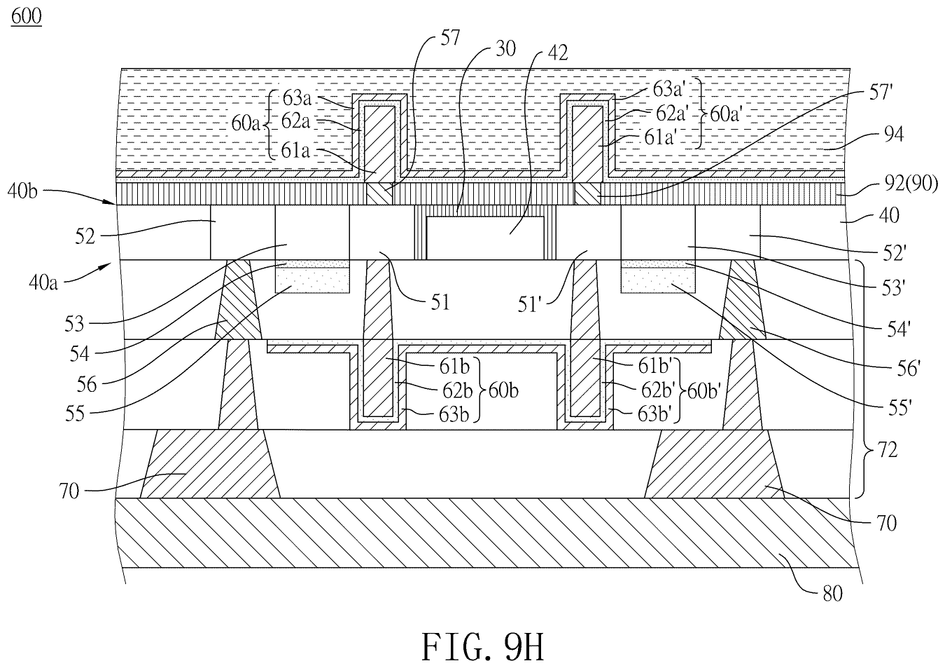

FIGS. 9A to 9K are schematic diagrams illustrating intermediate stages in the manufacture of a semiconductor structure according to one embodiment of the present disclosure.

As shown in FIG. 9A, a semiconductor substrate A3 is provided (step (a)). The semiconductor substrate A3 may be substantially similar to the semiconductor substrate A1 in FIG. 2A where like reference numerals indicate like elements. The semiconductor substrate A3 comprises a first substrate 10, a second substrate 40 on the first substrate 10, a bonding layer 20 between the first substrate 10 and the second substrate 40. In one embodiment, the bonding layer 20 may comprises silicon oxide. In one embodiment, the semiconductor substrate may be a silicon-on-insulator (SOI) substrate. The related details about the first substrate 10, the second substrate 40, and the bonding layer 20 described above may also apply here.

As shown in FIG. 9B, a portion of the second substrate 40 is removed to form a trench 45 extending through the second substrate 40 (step (g1)), and the bonding layer 20 may be exposed by the trench 45. Next, an etch stop layer 30 is formed at least on a bottom surface 47 of the trench 45 (step (g2)). In the embodiment shown in FIG. 9B, a portion of the etch stop layer 30 is formed over the first side 40a of the second substrate 40, and another portion of the etch stop layer 30 is formed lining sidewalls 48 and the bottom surface 47 of the trench 45. In some embodiments, the bonding layer 20 comprises silicon oxide, and the etch stop layer 30 may comprise silicon nitride, silicon oxynitride, doped semiconductor material, undoped semiconductor material, metal, or conductive metal compound. The trench 45 can be formed by performing suitable methods which may comprise photolithography, etching process such as reactive-ion etching (RIE), and/or any applicable process. The etch stop layer 30 may be formed by deposition process such as CVD, PVD, ALD, or the like. The related details about the etch stop layer 30 and the bonding layer 20 described above may also apply here.

As shown in FIG. 9C, an isolation structure 42 is formed in the trench 45 (step (g3)). The isolation structure 42 may comprise silicon oxide, silicon nitride, silicon oxynitride, fluoride-doped silicate (FSG), a low-k dielectric material, suitable material, or combinations thereof. The isolation structure 42 may be formed by suitable method(s) such as deposition process, e.g., CVD, PVD, ALD. In the embodiment shown in FIG. 9C, a portion of the etch stop layer 30 is removed to expose at least a portion of the second substrate 40 by suitable method(s) such as CMP, etching process, and/or the other applicable process. As such, a “lining” etch stop layer 30 is formed between the isolation structure 42 and the bonding layer 20.

As shown in FIG. 9D, a first source region 51, a second source region 51′, a first drain region 52 and a second drain region 52′ are formed in the second substrate 40, a first gate structure 55 and a first gate dielectric 54 are formed on a first side 40a of the second substrate 40, and a second gate structure 55′ and a second gate dielectric 54′ are formed on the first side 40a of the second substrate 40 (step (b)). In some embodiments, the materials and formation methods of the first source region 51, the second source region 51′, the first drain region 52, the second drain region 52′, the first body region 53, the second body region 53′, the first gate dielectric 54, the second gate dielectric 54′, the first gate structure 55, the second gate structure 55′ are similar to those described above with reference to FIG. 1 and FIG. 2C.

Next, a third capacitor 60b, and a fourth capacitor 60b′ are formed on the first side 40a of the second substrate 40. Specifically, dielectric layers 72 may be formed on the first side 40a of the second substrate 40 and the third capacitor 60b and the fourth capacitor 60b′ may be formed in one or more dielectric layer(s) of the dielectric layers 72. The third capacitor 60b is electrically connected to the first source region 51. The fourth capacitor 60b′ is electrically connected to the second source region 51′. In some embodiments, the materials and formation methods of the third capacitor 60b, the fourth capacitor 60b′, and the dielectric layers 72 are similar to those described above with reference to FIG. 1 and FIG. 2D. The first drain contact structure 56, the second drain contact structure 56′, and the interconnect structures 70 may also be formed in the dielectric layer 72 by similar material(s) and similar method(s) as described above with reference to FIG. 1 and FIG. 2D. The related details described above may apply here if applicable.

As shown in FIG. 9E, a third substrate 80 is added on the first side 40a of the second substrate 40, wherein the second substrate 40 is located between the third substrate 80 and the first substrate 10 (step (c)). The third substrate 80 may be bonded to the second substrate 40 or formed on the second substrate 40 by process(es) similar to that described above with regard to FIG. 2E. The related details about the third substrate 80 described above may apply here if applicable.

As shown in FIG. 9F, the first substrate 10 is removed to expose the bonding layer 20 (step (d1)). In some embodiments, the removal process may comprise selective etching that removes the first substrate 10 without etching completely through the bonding layer 20, and the bonding layer 20 may function as an etch stop layer. In some embodiments, the removal process may comprise grinding and/or CMP process. The bonding layer is then removed to expose the etch stop layer 30 and the second substrate 40 (step (d2)). The removal process may comprise selective etching that removes the bonding layer 20 while the etch stop layer 30 and the second substrate 40 remain substantially unchanged. For example, in an embodiment where the bonding layer 20 comprises silicon oxide, the etch stop layer 30 comprises silicon nitride, and the second substrate 40 comprises silicon, the bonding layer 20 can be etched using a first etchant such as dilute HF (e.g., a weight ratio of H₂O to HF at about 100:1). However, the disclosure is not limited thereto. Proper materials and proper etching conditions may be selected based on the actual needs. In the embodiment shown in FIG. 9F, the bonding layer 20 and the etch stop layer 30 are completely removed without using a mask, which may reduce manufacturing costs and fabrication time. During the etching process to remove the bonding layer 20, the etch stop layer 30 may prevent damage to the isolation structure 42, and therefore the isolation structure 42 may remain intact and may be able to provide better electrical isolation between cells.

As shown in FIG. 9G, a deposited dielectric layer 92 is formed on the second side 40b of the second substrate 40, wherein the etch stop layer 30 is located between the deposited dielectric layer 92 and the isolation structure 42. The dielectric layer 92 may be similar to that described above with reference to FIG. 1 and FIG. 2H and may be formed by deposition process such as PVD, CVD, or ALD, spin-on process, or any applicable process. The related details of the deposited dielectric layer 92 described above may apply here if applicable.

As shown in FIG. 9H, a first contact structure 57 and a second contact structure 57′ are formed extending through the deposited dielectric layer 92. The first contact structure 57 and the second contact structure 57′ may be similar to and may be formed by similar method(s) that described above with reference to FIG. 1 and FIG. 2J. The related details of the first contact structure 57 and the second contact structure 57′ described above may apply here if applicable.

Next, a first capacitor 60a and a second capacitor 60a′ are formed on the second side 40b of the second substrate 40 (step (e)). The first capacitor 60a is formed electrically connected to the first contact structure 57, and the second capacitor 60a′ is formed electrically connected to the second contact structure 57′. A second dielectric layer 94 may also be formed on the second side 40b of the second substrate 40 and over the deposited dielectric layer 92. The first capacitor 60a, the second capacitor 60a′, and the second dielectric layer 94 may be similar to and may be formed by similar method(s) that described above with reference to FIG. 1 and FIG. 2K.

The semiconductor structure 600 shown in FIG. 9H is substantially similar to the semiconductor structure 100 in FIG. 1, where like reference numerals indicate like elements. In the embodiment shown in FIG. 9H, the first dielectric layer 90 comprises the deposited dielectric layer 92. The etch stop layer 30 is disposed between the deposited dielectric layer 92 and the isolation structure 42. The etch stop layer 30 may also disposed between the first source region 51 and the isolation structure 42 and/or between the second source region 51′ and the isolation structure 42.

By methods disclosed herein, the fabrication of capacitors on the second side can become more easier. Moreover, it may be easier to form capacitors with a larger size and/or favorable configuration (e.g., favorable shape of the electrodes) on the “opened” second side of the substrate. In addition, forming capacitors on both sides of a transistor may increase the cell capacitance. The related details described above may apply here if applicable.

The semiconductor structures and methods of making the same described above may have one or more of the following advantages.

1. The semiconductor structures according to the present disclosure may include a capacitor on the second side of the transistor, which provides more flexibility in the shape and size of the capacitor. As such, capacitors with larger capacitance may be achieved and therefore may increase the equivalent capacitance and/or improve performance of each cell.

2. The semiconductor structures according to the present disclosure may include a capacitor on each side of the transistor and form an one transistor two capacitors (1T2C) memory cell. As such, the equivalent capacitance of each cell may be enhanced, and may provide required capacitance for a memory cell having a smaller cell size.

3. The semiconductor structures according to the present disclosure may include flat interfaces between the transistor and the first dielectric layer. As such, the plurality of transistors in a memory array may have more stable and uniform electrical performance and less leakage current due to less variations across cell regions and/or less defects occurred at the interfaces, especially when the semiconductor layer in which the cell regions is located is thin.

4. The semiconductor structures according to the present disclosure may include a first dielectric layer comprising oxide or low-k material which can function as an isolation layer between adjacent contact structures. As such, the distance between two contact structures may be shrink to 1 F to 2.5 F, and the cell size can be decreased correspondingly.

5. The methods according to the present disclosure provide processes through which one skilled in the art can make the semiconductor structures as described above. As such, the semiconductor structures can be made in a cost-effective way.

6. The methods according to the present disclosure provide processes through which one skilled in the art may provide a capacitor with a larger size and/or favorable configuration on the “opened” second side of the substrate.

7. The methods according to the present disclosure provide processes through which one skilled in the art may provide a semiconductor structure with capacitors on both sides of the transistor. As such, the cell capacitance may be increased.

8. The methods according to the present disclosure provide processes through which one skilled in the art may control the end point of the etching process to expose the source region during the formation process of the contact structures. The etch stop layer may prevent over-etching of the source region, and therefore, it may be easier to form contact structures physically and electrically connected to respective source region in each of the plurality of cells.

The foregoing description of embodiments is provided to enable any person skilled in the art to make and use the subject matter. Various modifications to these embodiments will be readily apparent to those skilled in the art, and the novel principles and subject matter disclosed herein may be applied to other embodiments without the use of the innovative faculty. The claimed subject matter set forth in the claims is not intended to be limited to the embodiments shown herein but is to be accorded the widest scope consistent with the principles and novel features disclosed herein. It is contemplated that additional embodiments are within the spirit and true scope of the disclosed subject matter. Thus, it is intended that the present invention covers modifications and variations that come within the scope of the appended claims and their equivalents.

What is claimed is:

1. A semiconductor structure, comprising:
a semiconductor layer comprising a first cell region and a second cell region, the first cell region comprising a first source region, a first drain region, and a first body region between the first source region and the first drain region, the second cell region comprising a second source region, a second drain region, and a second body region between the second source region and the second drain region;
a first gate structure on a first side of the semiconductor layer and over the first body region; and
a second gate structure on the first side of the semiconductor layer and over the second body region;
a first dielectric layer on a second side of the semiconductor layer opposite from the first side, wherein the first dielectric layer is in contact with the semiconductor layer and overlapped with both the first source region and the second source region;
a first capacitor on the second side of the semiconductor layer and electrically connected to the first source region; and
a second capacitor on the second side of the semiconductor layer and electrically connected to the second source region.

2. The semiconductor structure of claim 1, wherein a thickness of the first dielectric layer ranges from about 2 nm to about 700 nm.

3. The semiconductor structure of claim 1 further comprising an isolation structure between the first source region and the second source region.

4. The semiconductor structure of claim 3, wherein the first dielectric layer overlaps and is in contact with the isolation structure.

5. The semiconductor structure of claim 3, wherein a first interface between the first dielectric layer and the first cell region extends laterally across the first source region, the first drain region, and the first body region; a second interface between the first dielectric layer and the second cell region extends laterally across the second source region, the second drain region, and the second body region; and a third interface between the first dielectric layer and the isolation structure extends from the first interface to the second interface.

6. The semiconductor structure of claim 5, wherein the first interface, the second interface, and the third interface collectively form a flat interface having a flatness less than 2 μm and a smoothness less than 2 nm.

7. The semiconductor structure of claim 1 further comprising a third capacitor and a fourth capacitor on the first side of the semiconductor layer, wherein the third capacitor is electrically connected to the first source region, and the fourth capacitor is electrically connected to the second source region.

8. The semiconductor structure of claim 1, wherein the first dielectric layer comprises an etch stop layer comprising silicon nitride or silicon oxynitride.

9. The semiconductor structure of claim 1, wherein the first dielectric layer comprises an intermediate layer comprising silicon oxide or low-k dielectric material.

10. The semiconductor structure of claim 1, wherein the first capacitor comprises a first electrode electrically connected to the first source region, a second electrode, and a capacitor dielectric between the first electrode and the second electrode.

11. The semiconductor structure of claim 10, wherein each of the first electrode and the second electrode comprises polysilicon, metal, or conductive metal compound.

12. The semiconductor structure of claim 10, wherein the capacitor dielectric comprises high-k material.

13. The semiconductor structure of claim 10, wherein the first electrode is container-shaped, pillar-shaped, multi-fin-shaped, or plate-shaped.

14. The semiconductor structure of claim 1 further comprising a first contact structure extending through the first dielectric layer and a second contact structure extending through the first dielectric layer, wherein the first capacitor is electrically connected to the first source region through the first contact structure, and the second capacitor is electrically connected to the second source region through the second contact structure.

15. The semiconductor structure of claim 14, wherein a height of the first contact structure is substantially equal to a thickness of the first dielectric layer.

16. The semiconductor structure of claim 14, wherein a height of the first contact structure is in a range between about 2 nm and about 700 nm.

17. The semiconductor structure of claim 14, wherein a lateral interval between the first contact structure and the second contact structure is less than 2.5 times a minimum critical dimension.

18. The semiconductor structure of claim 1, wherein the semiconductor layer comprises a single crystalline semiconductor material.

19. A method for manufacturing a semiconductor structure, comprising:
(a) providing a semiconductor substrate comprising a first substrate, a second substrate on the first substrate, and a bonding layer between the first substrate and the second substrate;
(b) forming a source region and a drain region in the second substrate and forming a gate structure on a first side of the second substrate;
(c) adding a third substrate on the first side of the second substrate, wherein the second substrate is between the third substrate and the first substrate;
(d) removing the first substrate and the bonding layer;
(e) forming a first capacitor on a second side of the second substrate opposite from the first side, wherein the first capacitor is electrically connected to the source region.

20. The method of claim 19, wherein the semiconductor substrate further comprises an etch stop layer between the bonding layer and the second substrate, and the method further comprises (f) removing at least a portion of the etch stop layer before the step (e).

21. The method of claim 20, wherein the bonding layer comprises silicon oxide, and the etch stop layer comprises silicon nitride, silicon oxynitride, doped semiconductor material, undoped semiconductor material, metal, or conductive metal compound.

22. The method of claim 20, wherein the step (f) comprises forming an opening extending through the etch stop layer to expose the source region and forming a contact structure in the opening, and the step (e) comprises forming the first capacitor electrically connected to the contact structure.

23. The method of claim 19, wherein the second substrate comprises silicon, germanium, silicon germanium, gallium arsenide (GaAs), indium phosphide (InP), silicon carbide (SiC), or gallium nitride (GaN).

24. The method of claim 19 further comprising forming a dielectric layer on the second side of the second substrate after the step (d).

25. The method of claim 24 further comprising forming an opening extending through the dielectric layer to expose the source region and forming a contact structure in the opening, wherein the step (e) comprises forming the first capacitor electrically connected to the contact structure.

26. The method of claim 20, wherein the semiconductor substrate further comprises an intermediate layer between the etch stop layer and the second substrate.

27. The method of claim 26, wherein the intermediate layer comprises silicon oxide or low-k dielectric material.

28. The method of claim 26, wherein the step (f) comprises removing the etch stop layer to expose the intermediate layer.

29. The method of claim 26 further comprising forming an opening extending through the intermediate layer to expose the source region and forming a contact structure in the opening, wherein the step (e) comprises forming the first capacitor electrically connected to the contact structure.

30. The method of claim 19 further comprising forming interconnect structures on the first side of the second substrate before the step (c), wherein the interconnect structures are electrically connected to the drain region or the gate structure.

31. The method of claim 19 further comprising forming a second capacitor on the first side of the second substrate before the step (c), wherein the second capacitor is electrically connected to the source region.

32. The method of claim 19, wherein the step (d) comprises etching the bonding layer with a first etchant.

33. The method of claim 19, wherein the step (d) comprises completely removing the bonding layer of the semiconductor substrate.

34. The method of claim 20, wherein the step (f) comprises etching the etch stop layer with a second etchant.

35. The method of claim 19 further comprising (g) forming an isolation structure before the step (c).

36. The method of claim 35, wherein the step (g) comprises:
(g1) removing a portion of the second substrate to form a trench extending through the second substrate;
(g2) forming an etch stop layer on a bottom surface of the trench; and
(g3) forming the isolation structure in the trench.

37. The method of claim 36, wherein the step (d) comprises:
(d1) removing the first substrate to expose the bonding layer; and
(d2) removing the bonding layer to expose the etch stop layer.
